(19) United States
(12) Patent Application Publication
(10) Pub. No.: US 2026/0150182 A1
(43) Pub. Date: May 28, 2026

(54) ELECTRONIC DEVICE

(71) Applicant: SAMSUNG ELECTRONICS CO., LTD., Suwon-si (KR)

(72) Inventors: Sangil IM, Suwon-si (KR); Yonghee AN, Suwon-si (KR); Pilwon SEO, Suwon-si (KR); Jeongseob KIM, Suwon-si (KR); Junhee HAN, Suwon-si (KR)

(21) Appl. No.: 19/447,345

(22) Filed: Jan. 13, 2026

Related U.S. Application Data
(63) Continuation of application No. PCT/KR2024/010384, filed on Jul. 18, 2024.

(30) Foreign Application Priority Data
Jul. 20, 2023 (KR) 10-2023-0094509
Aug. 29, 2023 (KR) 10-2023-0113883

(51) Int. Cl. H05K 1/02; G06F 1/16; G06F 1/20; H04M 1/02; H05K 7/20; H05K 9/00

(52) U.S. Cl. CPC H05K 1/0215; G06F 1/1658; G06F 1/203; H04M 1/0277; H05K 1/0203; H05K 7/20336; H05K 7/2039; H05K 9/006; G06F 2200/201; H05K 2201/0707; H05K 2201/10984

(57) ABSTRACT

An electronic device may include: a display; a conductive plate facing the display; a first circuit board including a first opening having an electronic component disposed thereon; a second circuit board having an integrated circuit disposed thereon, wherein the integrated circuit is disposed in the first opening; a shield can having a second opening and disposed on the first circuit board to surround the periphery of the electronic component; a shielding member covering the second opening; a vapor chamber disposed between the conductive plate and the shielding member when the display is viewed from a first direction; a first conductive member electrically connecting the conductive plate and the vapor chamber; and a second conductive member electrically connecting the vapor chamber and the shield can. The second conductive member may be disposed so as not to overlap the shielding member when viewed from the first direction.

### CROSS-REFERENCE TO RELATED APPLICATIONS

This application is a continuation of International Application No. PCT/KR2024/010384 designating the United States, filed on Jul. 18, 2024, in the Korean Intellectual Property Receiving Office and claiming priority to Korean Patent Application Nos. 10-2023-0094509, filed on Jul. 20, 2023, and 10-2023-0113883, filed on Aug. 29, 2023, in the Korean Intellectual Property Office, the disclosures of each of which are incorporated by reference herein in their entireties.

### BACKGROUND

### Field

The disclosure relates to an electronic device including a conductive member (e.g., a conductive gasket) electrically connecting a printed circuit board (PCB) and a vapor chamber.

### Description of Related Art

An electronic device may refer to a device that performs a specified function based on a program installed therein, such as a home appliance, an electronic scheduler, a portable multimedia player, a mobile communication terminal, a tablet PC, a video/audio device, a desktop/laptop PC, or a vehicle navigation system. An electronic device may include a first PCB (e.g., a main PCB) on which electronic components and peripheral circuits are disposed, and a second printed circuit (PCB) (e.g., a core PCB) on which processors (e.g., an application processor (AP) or a central processing unit (CPU)) are disposed. An electronic device may include shielding components (e.g., shielding members) for shielding noise (e.g., electromagnetic waves) generated from processors and electronic components. An electronic device may include a heat dissipation component (e.g., a thermal interface material (TIM), a heat-spreading plate) for releasing heat (e.g., dissipating heat) generated from processors and electronic components.

Electronic components having high power consumption per unit area (e.g., power density), such as processors and electronic components, are applied to electronic devices. High power consumption per unit area in processors and electronic components may lead to heat generation in electronic devices when these components are disposed on printed circuit boards (PCBs) with a limited area. When the temperature of the heat generated from an electronic device increases, the performance of the electronic device may be reduced, and the lifetimes of processors and electronic components may be shortened. The increased heat generation temperature may raise the temperature of the external surface of the electronic device, which may cause discomfort to the user. In addition, high-power processors and electronic components may not only generate heat but also produce noise (e.g., electromagnetic waves). Noise (e.g., electromagnetic waves) generated from electronic components may cause degradation in performance and lifespan of surrounding components and circuits, and may cause malfunctions of electronic devices. In addition, noise (e.g., electromagnetic waves) generated from electronic devices may have a harmful effect on the human body.

The above-described information is provided as background information for facilitating understanding of the disclosure. No assertion or determination is made as to whether the above contents may be applied as prior art in relation to the disclosure.

In order to dissipate heat generated from components of an electronic device, heat dissipation components (e.g., a TIM, a heat-spreading plate) may be applied. In order to shield noise (e.g., electromagnetic waves) generated from components of an electronic device, a metal frame (e.g., a metal plate) and a shield can that surrounds processors and electronic components may be applied. The contact of a ground path using a conductive clip (e.g., a C-clip) may have an increased shielding (or removal) effect as it is closer to the position of a component that generates noise (e.g., electromagnetic waves), and a decreased shielding (or removal) effect as it becomes farther away from the position. In order to increase the shielding (or removal) effect of noise (e.g., electromagnetic waves) generated from a processor, a conductive clip (e.g., a C-clip) should be disposed at a position adjacent to the processor. However, since the area of a second PCB (e.g., a processor PCB, a core circuit board) is smaller than that of a first PCB (e.g., a main PCB, a main circuit board), there are limitations in forming a ground path using a conductive clip (e.g., a C-clip) on the second PCB (e.g., a processor PCB, a core circuit board).

### SUMMARY

Embodiments of the disclosure may provide an electronic device in which noise (e.g., electromagnetic waves) generated from the processor and the second PCB (e.g., a processor PCB, a core circuit board) may be shielded (e.g., removed) by forming a ground path contact in a portion adjacent to a processor and a second PCB (e.g., a processor PCB, a core circuit board).

An electronic device according to an example embodiment of the disclosure may include: a display, a conductive plate facing the display, a first circuit board (e.g., a first PCB) having a first opening formed therein and an electronic component disposed thereon, a second circuit board (e.g., a second PCB) having an integrated circuit (e.g., a processor) disposed thereon to be positioned within the first opening, a shield can having a second opening and disposed on the first circuit board to surround a peripheral portion of the electronic component, a shielding member comprising an thermally conductive material configured to cover the second opening, a vapor chamber disposed between the conductive plate and the shielding member when the display is viewed in a first direction, a first conductive member comprising a conductive material configured to electrically connect the conductive plate and the vapor chamber, and a second conductive member comprising a conductive material configured to electrically connect the vapor chamber and the shield can. When viewed in the first direction, the second conductive member may be disposed so as not to overlap the shielding member.

According to an example embodiment of the disclosure, an electronic device may include: a display, a conductive plate facing the display, a first circuit board (first PCB) having a first opening formed therein and an electronic component disposed thereon, a second circuit board (second PCB) having an integrated circuit (processor) disposed thereon to be positioned within the first opening, a shield can having a second opening and disposed on the first circuit board (first PCB) to surround a peripheral portion of the electronic component, a shielding member comprising a thermally conductive material configured to cover the second opening, a vapor chamber disposed between the conductive plate and the shielding member when the display is viewed in a first direction, and a conductive member comprising a conductive material configured to electrically connect the conductive plate and the vapor chamber. The shield can and the vapor chamber may be electrically connected to form a ground path between the first circuit board (first PCB) and the conductive plate.

In an electronic device according to an example embodiment of the disclosure, noise (e.g., electromagnetic waves) generated from a processor and a second PCB (e.g., a processor PCB, a core circuit board) may be shielded (e.g., removed) by forming a ground path contact in a portion adjacent to a processor and a second PCB (e.g., a processor PCB, a core circuit board).

In an electronic device according to an example embodiment of the disclosure, noise (e.g., electromagnetic waves) generated from the processor and the second PCB (e.g., a processor PCB, a core circuit board) may be shielded (e.g., removed) by forming a ground path contact at a portion adjacent to a processor and a second PCB (e.g., a processor PCB, a core circuit board). By applying a second conductive member (e.g., a gasket) to the electronic device to form a ground path between a first PCB (e.g., a main PCB or a main circuit board) and a conductive plate (e.g., a metal rear), total isotropic sensitivity (TIS) may be improved for various frequency bands (e.g., LTE bands 28, 20, 5, 8, 3, 17, 2, 4, and 66).

In an electronic device according to an example embodiment of the disclosure, noise (e.g., electromagnetic waves) generated from a processor and a second PCB (e.g., a processor PCB, a core circuit board) may be shielded (e.g., removed) by forming a ground path contact using a shield can and a conductive clip. When a shield can and a conductive clip are applied to an electronic device to form a ground path between a first PCB (e.g., a main PCB, a main circuit board) and a conductive plate (e.g., a metal rear), TIS may be improved for frequency bands (e.g., LTE bands 28, 20, 5, 8, 3, 17, 2, 4, and 66).

The effects that may be obtained by the disclosure are not limited to those mentioned above, and other effects not mentioned may be clearly understood by a person ordinarily skilled in the art to which the disclosure pertains based on the following description.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

In connection with the description of the drawings, the same or similar components may be denoted by the same or similar reference numerals.

FIG. 1 is a block diagram of an example electronic device in a network environment according to various embodiments.

FIGS. 2A and 2B are diagrams illustrating front and rear views of an example electronic device in a first state (e.g., an unfolded state) according to various embodiments.

FIGS. 2C and 2D are diagrams illustrating front and rear views of the electronic device in a second state (e.g., a folded state) according to various embodiments.

FIG. 3A is a front perspective view of an example electronic device illustrating a first surface (e.g., the front surface) according to various embodiments.

FIG. 3B is a rear perspective view of the electronic device illustrating a second surface (e.g., the rear surface) according to various embodiments.

FIG. 4 is a block diagram illustrating an example configuration of an electronic device according to various embodiments.

FIG. 5 is a cross-sectional view illustrating an electronic device in which a ground path is formed between a main PCB and a vapor chamber using a C-clip according to various embodiments.

FIG. 6 is a diagram illustrating an example of how a C-clip is electrically connected to a main PCB according to various embodiments.

FIG. 7 is a diagram illustrating noise and heat generated from a core PCB on which a processor is disposed according to various embodiments.

FIGS. 8 and 9 are a diagram and cross-sectional view illustrating an electronic device, which includes a conductive member (e.g., a conductive gasket) electrically connecting a main PCB and a vapor chamber, according to various embodiments.

FIG. 10A is a cross-sectional view illustrating an electronic device, including a conductive member (e.g., a conductive gasket) electrically connecting a main PCB and a vapor chamber, according to various embodiments.

FIG. 10B is a diagram illustrating an example of how a second conductive member (gasket) is disposed within an opening of a shielding member (e.g., a metal TIM) according to various embodiments.

FIG. 11 is a cross-sectional view illustrating an electronic device, including a conductive member (e.g., a conductive gasket) electrically connecting a main PCB and a vapor chamber, according to various embodiments.

FIG. 12 is a partial cross-sectional view illustrating an example of how a conductive member (e.g., a conductive gasket) is disposed inside a shielding member (e.g., a metal thermal interface material (metal TIM)) according to various embodiments.

FIG. 13 is a cross-sectional view illustrating an example structure of a shielding member (e.g., a metal TIM) according to various embodiments.

FIG. 14A is a cross-sectional view illustrating an electronic device, which includes a conductive member (e.g., a conductive gasket) electrically connecting a main PCB and a vapor chamber, according to various embodiments.

FIG. 14B is a diagram illustrating an example shape of the shield can illustrated in FIG. 14A according to various embodiments.

FIG. 15A is a cross-sectional view illustrating an electronic device including a shield can electrically connecting a main PCB and a vapor chamber according to various embodiments.

FIG. 15B is a cross-sectional view illustrating a groove formed on an upper surface of the vapor chamber illustrated in FIG. 15A according to various embodiments.

FIG. 16 is a cross-sectional view illustrating an electronic device, including a conductive member (e.g., a conductive gasket) electrically connecting a main PCB and a vapor chamber, according to various embodiments.

FIG. 17 is a cross-sectional view illustrating an electronic device including a shield can electrically connecting a main PCB and a vapor chamber according to various embodiments.

FIG. 18 is a perspective view illustrating the shield can illustrated in FIG. 17 according to various embodiments.

FIG. 19 is a cross-sectional view illustrating an electronic device including a shield can electrically connecting a main printed circuit board (PCB) and a vapor chamber according to various embodiments.

FIG. 20 is a perspective view and diagram illustrating how a shield can pin is electrically connected to a conductive clip according to various embodiments.

It should be noted that throughout the drawings, the same reference numbers are used to describe the same or similar elements, features, and structures.

### DETAILED DESCRIPTION

The following description made with reference to the accompanying drawings is provided to assist in a comprehensive understanding of various example embodiments of the disclosure. Although various specific details are included herein to aid in understanding, they should be regarded as merely illustrative. Accordingly, those ordinarily skilled in the art will recognize that various changes and modifications to the various example embodiments described herein may be made without departing from the spirit and scope of the disclosure. Furthermore, descriptions of well-known functions and components may be omitted for clarity and conciseness.

The terms and words used in the following description and claims are not limited to their literal meanings but are used merely by the applicant to enable a clear and consistent understanding of the disclosure. Therefore, it should be apparent to those ordinarily skilled in the art that the following descriptions of various embodiments of the disclosure are provided for illustrative purposes only and are not intended to limit the disclosure as defined by the appended claims and their equivalents.

The singular forms should be understood to include the plural unless the context clearly indicates otherwise. Accordingly, for example, a reference to a “component surface” may include a reference to one or more of such surfaces.

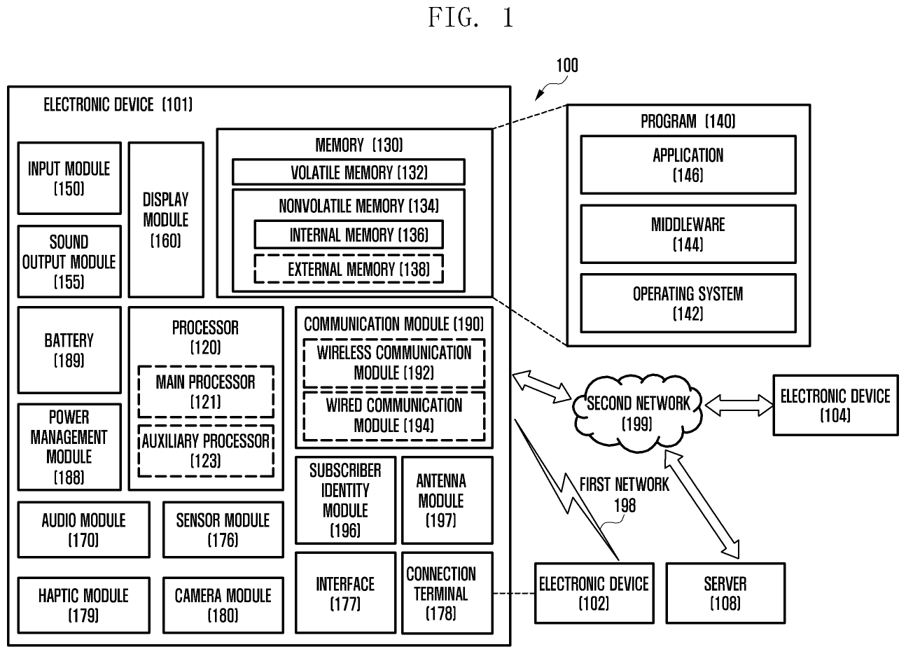

FIG. 1 is a block diagram illustrating an example electronic device in a network environment according to various embodiments.

Referring to FIG. 1, the electronic device 101 in the network environment 100 may communicate with an electronic device 102 via a first network 198 (e.g., a short-range wireless communication network), or with an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to an embodiment, a display module 160 may include a flexible display configured to be foldable or unfoldable.

According to an embodiment, the display module 160 may include a flexible display that is disposed to be slidable in a first direction (e.g., slidable in the x-axis direction) or a second direction (e.g., slidable in the y-axis direction) and provides a screen (e.g., a display screen).

According to an embodiment, the display module 160 may also be referred to as a variable display (e.g., a stretchable display), an expandable display, or a slide-in/out display.

According to an embodiment, the display module 160 may include a bar-type or plate-type display.

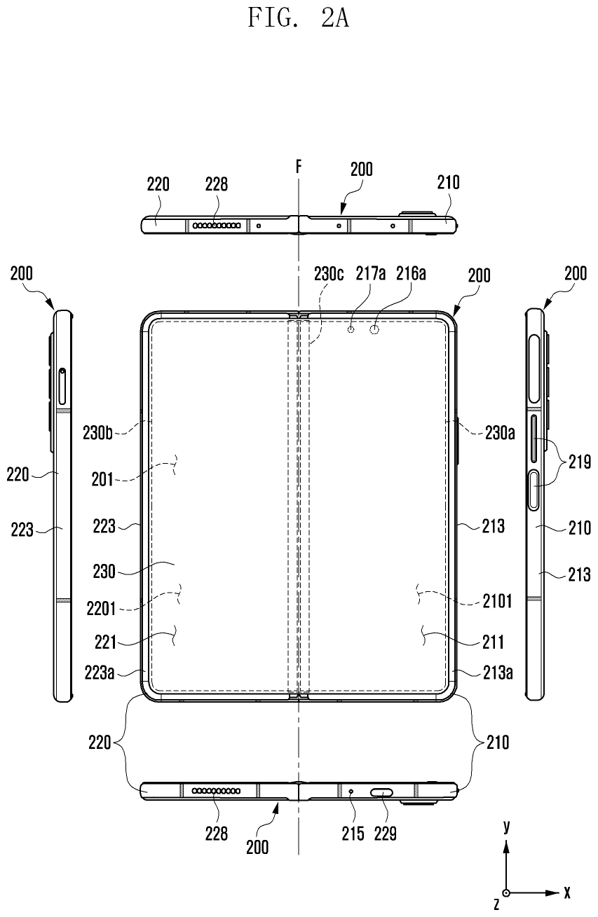

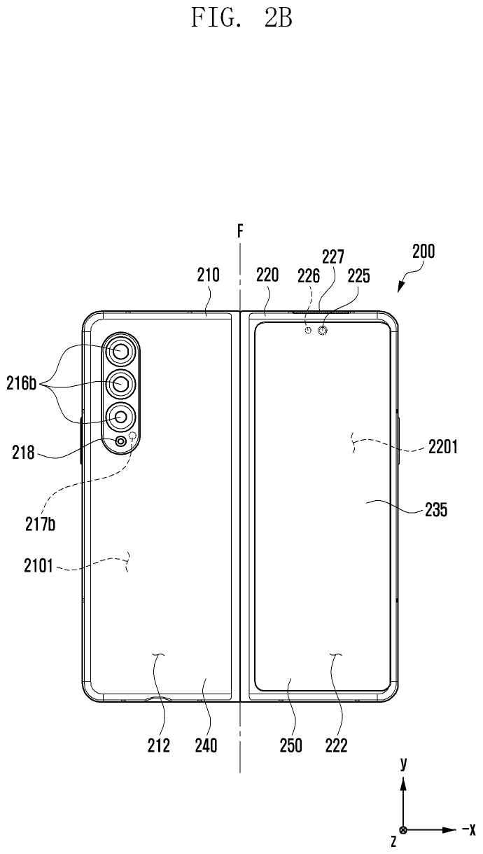

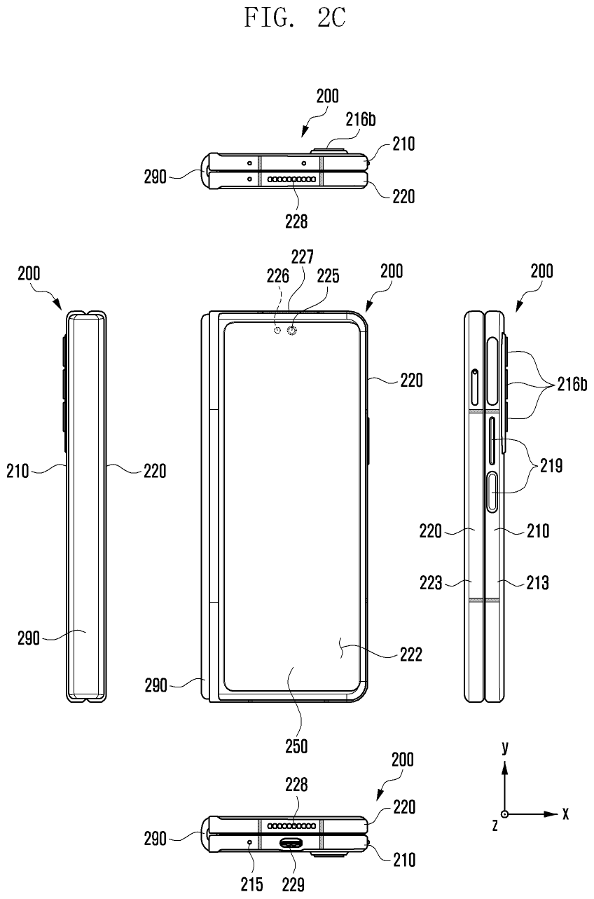

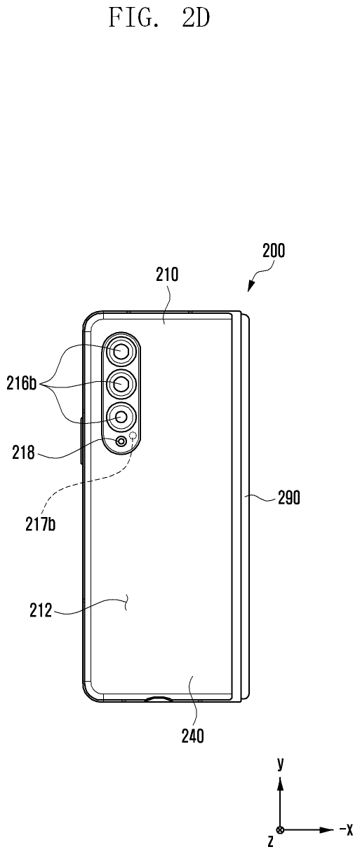

FIGS. 2A and 2B are diagrams illustrating front and rear views of an example electronic device in a first state (e.g., an unfolded stage) according to various embodiments. FIGS. 2C and 2D are diagrams illustrating front and rear views of an example electronic device in a second state (e.g., a folded state) according to various embodiments.

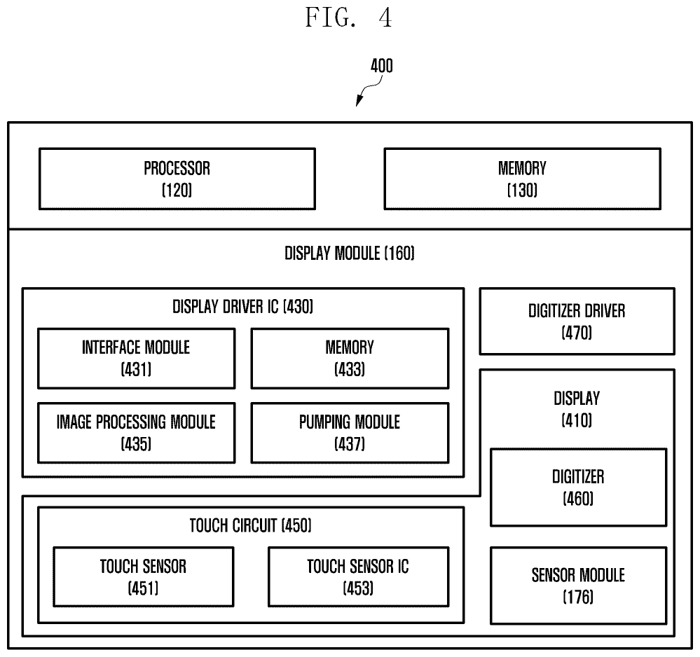

Referring to FIGS. 2A to 2D, an electronic device 200 (e.g., the electronic device 101 of FIG. 1 or the electronic device 400 of FIG. 4) according to an embodiment of the disclosure may include a pair of housings 210 and 220 (e.g., a foldable housing structure) coupled to each other to be rotatable about a folding axis F through at least one hinge device (e.g., a hinge module or a hinge structure) so as to be foldable relative to each other, a first display 230 (e.g., a flexible display, a foldable display, or a main display) disposed on the pair of housings 210 and 220, and a second display 235 (e.g., a sub-display) disposed on the second housing 220.

According to an embodiment, at least a portion of the at least one hinge device may be disposed so as to be invisible from the outside through the first housing 210 and the second housing 220, and in the first state (e.g., the unfolded state), so as to be invisible from the outside through a hinge housing 290 (e.g., a hinge cover) that covers the foldable portion. Herein, the surface on which the first display 230 is disposed may be defined as the front surface of the electronic device 200. Herein, the opposite surface of the front surface may be defined as the rear surface of the electronic device 200. In addition, the surface surrounding the space between the front surface and the rear surface may be defined as the side surface of the electronic device 200.

According to an embodiment, the pair of housings 210 and 220 may include a first housing 210 and a second housing 220 that are foldable relative to each other through at least one hinge device.

According to an embodiment, the pair of housings 210 and 220 are not limited to the shapes and assemblies illustrated in FIGS. 2A to 2D, but may be implemented by other shapes or other combinations and/or assemblies of components.

According to an embodiment, the first housing 210 and the second housing 220 may be disposed on opposite sides of the folding axis F, may have shapes that are generally symmetrical to each other with respect to the folding axis F, and may be folded to match each other.

According to an embodiment, the first housing 210 and the second housing 220 may be folded asymmetrically with respect to the folding axis F.

According to an embodiment, the first housing 210 and the second housing 220 may have different angles or distances from each other depending on whether the electronic device 200 is in a first state (e.g., an unfolded state), a second state (e.g., a folded state), or a third state (e.g., an intermediate state). For example, the electronic device 200 may detect whether it is in the first state (e.g., the unfolded state), the second state (e.g., the folded state), or the third state (e.g., the intermediate state) using a sensor module (e.g., the sensor module 176 of FIG. 1). The electronic device 200 may detect an angle formed between the first housing 210 and the second housing 220 using a sensor module (e.g., the sensor module 176 of FIG. 1).

According to an embodiment, the first housing 210 may be connected to at least one hinge device in the first state (e.g., the unfolded state) of the electronic device 200. The first housing 210 may include a first surface 211 oriented in a forward direction of the electronic device 200, a second surface 212 oriented in an opposite direction from the first surface 211, and/or a first side surface member 213 that surrounds at least a portion of a first space 2101 between the first surface 211 and the second surface 212.

According to an embodiment, the second housing 220 may be connected to at least one hinge device in the first state (e.g., the unfolded state) of the electronic device 200. The second housing 220 may include a third surface 221 oriented in the forward direction of the electronic device 200, a fourth surface 222 oriented in an opposite direction from the third surface 221, and/or a second side surface member 223 that surrounds at least a portion of a second space 2201 between the third surface 221 and the fourth surface 222.

According to an embodiment, the first surface 211 may have substantially the same direction as the third surface 221 in the first state (e.g., an unfolded state), and may at least partially face the third surface 221 in the second state (e.g., a folded state).

According to an embodiment, the electronic device 200 may further include a recess 201 defined to accommodate the first display 230 through structural coupling between the first housing 210 and the second housing 220.

According to an embodiment, the recess 201 may have substantially the same size as the first display 230.

According to an embodiment, the first housing 210 may be coupled to the first side surface member 213 when the first display 230 is viewed from above. The first housing 210 may include a first protective frame 213a (e.g., a first decoration member) that covers an edge of the first display 230 so as to be invisible from the outside by overlapping the edge of the first display 230.

According to an embodiment, the first protective frame 213a may be integrated with the first side surface member 213.

According to an embodiment, the second housing 220 may be coupled to the second side surface member 223 when the first display 230 is viewed from above. The second housing 220 may include a second protective frame 223a that covers an edge of the first display 230 so as to be invisible from the outside by overlapping the edge of the first display 230.

According to an embodiment, the second protective frame 223a may be integrated with the second side surface member 223. In an embodiment, the first protective frame 213a and the second protective frame 223a may be omitted.

According to an embodiment, the hinge housing 290 (e.g., a hinge cover) may be disposed between the first housing 210 and the second housing 220. The hinge housing 290 may be disposed so as to cover at least a portion (e.g., at least one hinge module) of at least one hinge device.

According to an embodiment, the hinge housing 290 may be covered by a portion of the first housing 210 and the second housing 220, or may be exposed to the outside, depending on whether the electronic device 200 is in a first state (e.g., an unfolded state), a second state (e.g., a folded state), or a third state (e.g., a middle state). For example, when the electronic device 200 is in the first state (e.g., the unfolded state), at least a portion of the hinge housing 290 may be covered by the first housing 210 and the second housing 220 to be substantially invisible from the outside.

According to an embodiment, when the electronic device 200 is in the second state (the folded state), at least a portion of the hinge housing 290 may be disposed to be visible from the outside between the first housing 210 and the second housing 220.

According to an embodiment, when the first housing 210 and the second housing 220 are in a third state (intermediate state) in which they form a predetermined angle, the hinge housing 290 may be disposed to at least partially be visible from the outside of the electronic device 200 between the first housing 210 and the second housing 220. For example, the region of the hinge housing 290 exposed to the outside may be smaller than that in the case where the electronic device is fully folded. According to an embodiment, the hinge housing 290 may include a curved surface.

According to an embodiment, when the electronic device 200 is in the first state (e.g., the unfolded state), the first housing 210 and the second housing 220 may form an angle of about 180 degrees, and the first region 230a, the second region 230b, and the folding region 230c of the first display 230 may form a substantially same plane. The first region 230a, the second region 230b, and the folding region 230c of the first display 230 may be oriented in substantially the same direction (e.g., the z-axis direction). As an example, when the electronic device 200 is in the first state (e.g., the unfolded state), the first housing 210 may be rotated relative to the second housing 220 by about 360 degrees so as to be folded in an opposite direction such that the second surface 212 and the fourth surface 222 face each other (e.g., an out-folding type).

According to an embodiment, when the electronic device 200 is in the second state (the folded state), the first surface 211 of the first housing 210 and the third surface 221 of the second housing 220 may be disposed to face each other. In this case, the first region 230a and the second region 230b of the first display 230 may form a narrow angle (e.g., in a range of 0 degrees to about 10 degrees) with each other via the folding region 230c and may be disposed to face each other. According to an embodiment, at least a portion of the folding region 230c may be transformed into a curved shape with a predetermined curvature.

According to an embodiment, when the electronic device 200 is in the third state (intermediate state), the first housing 210 and the second housing 220 may be disposed at a certain angle relative to each other. In this case, the first region 230a and the second region 230b of the first display 230 may form an angle greater than that in the second state (e.g., the folded state) and smaller than that in the first state (e.g., the unfolded state), and the curvature of the folding region 230c may be smaller than that in the second state (e.g., the folded state) and greater than that in the first state (e.g., the unfolded state). In an embodiment, the first housing 210 and the second housing 220 may form an angle that allows them to stop at a predetermined folding angle between the second state (e.g., a folded state) and the third state (e.g., a middle state) through the at least one hinge device (e.g., a free stop function). In an embodiment, the first housing 210 and the second housing 220 may be continuously operated while being pressed in the folding or unfolding direction with reference to a designated inflection angle via at least one hinge device.

According to an embodiment, the electronic device 200 may include at least one of the following components: one or more displays 230 and 235, input devices 215, sound output devices 227 and 228, sensor modules 217a, 217b, and 226, camera modules 216a, 216b, and 225, key input devices 219, indicators (not illustrated), or connector ports 229 which are disposed in or on the first housing 210 and/or the second housing 220. In an embodiment, in the electronic device 200, at least one of the components may be omitted, or at least one other component may be additionally included.

According to an embodiment, the one or more displays 230 and 235 may include a first display 230 (e.g., a flexible display) disposed to be supported by the first surface 211 of the first housing 210 and the third surface 221 of the second housing 220 via the at least one hinge device, and a second display 235 disposed in the internal space of the second housing 220 to be at least partially visible from the outside through the fourth surface 222.

In an embodiment, the second display 235 may be disposed in the internal space of the first housing 210 to be visible from the outside through the second surface 212.

According to an embodiment, the first display 230 may be mainly used in the first state (e.g., the unfolded state) of the electronic device 200. The second display 235 may also be used when the electronic device 200 is in the first state (e.g., the unfolded state).

According to an embodiment, the second display 235 may be mainly used in the second state (e.g., the folded state) of the electronic device 200. The first display 230 may also be used when the electronic device 200 is in the second state (e.g., the folded state).

According to an embodiment, when the electronic device 200 is in the third state (e.g., an intermediate state), the first display 230 and/or the second display 235 may be controlled to be usable based on the folding angle between the first housing 210 and the second housing 220.

According to an embodiment, the first display 230 may be disposed in an accommodation space defined by the pair of housings 210 and 220. For example, the first display 200 may be disposed in the recess 201 defined by the pair of housings 210 and 220, and may be disposed to occupy substantially most of the front surface of the electronic device 200 in the first state (e.g., the unfolded state). According to an embodiment, the first display 230 may include a flexible display, at least a portion of which is transformable into a flat shape or a curved shape.

According to an embodiment, the first display 230 may include a first region 230a facing the first housing 210 and a second region 230b facing the second housing 220. According to an embodiment, the first display 230 may include a folding region 230c including a portion of the first region 230a and a portion of the second region 230b with reference to the folding axis F.

According to an embodiment, at least a portion of the folding region 230c may include a region corresponding to the at least one hinge device.

According to an embodiment, the region division of the first display 230 is merely an example physical division based on the pair of housings 210 and 220 and the at least one hinge device, and in practice, the first display 230 may display a single seamless entire screen via the pair of housings 210 and 220 and the at least one hinge device.

According to an embodiment, the first region 230a and the second region 230b may have an overall symmetrical shape or a partially asymmetrical shape with respect to the folding region 230c.

According to an embodiment, the electronic device 200 may include a first rear surface cover 240 disposed on the second surface 212 of the first housing 210 and a second rear surface cover 250 disposed on the fourth surface 222 of the second housing 220. In an embodiment, at least a portion of the first rear surface cover 240 may be integrated with the first side surface member 213. In an embodiment, at least a portion of the second rear surface cover 250 may be integrated with the second side surface member 223.

According to an embodiment, at least one of the first rear surface cover 240 and the second rear surface cover 250 may be made of a substantially transparent plate (e.g., a glass plate including various coating layers, or a polymer plate) or an opaque plate. According to an embodiment, the first rear surface cover 240 may be made of, for example, coated or colored glass, ceramic, polymer, metal (e.g., aluminum, stainless steel (STS), or magnesium), or an opaque plate such as a combination of two or more of these materials.

According to an embodiment, the second rear surface cover 250 may be made of a substantially transparent plate such as glass or a polymer. Accordingly, the second display 235 may be disposed in the internal space of the second housing 220 so as to be visible from the outside through the second rear surface cover 250.

According to an embodiment, the input devices 215 may include a microphone. In an embodiment, the input devices 215 may include a plurality of microphones disposed to detect the direction of sound.

According to an embodiment, the sound output devices 227 and 228 may include speakers. According to an embodiment, the sound output devices 227 and 228 may include a call receiver 227 disposed through the fourth surface 222 of the second housing 220, and an external speaker 228 disposed through at least a portion of the second side surface member 223 of the second housing 220.

In an embodiment, the input devices 215, the sound output devices 227 and 228, and the connector ports 229 may be disposed in spaces of the first housing 210 and/or the second housing 220. The input devices 215, the sound output devices 227 and 228, and the connector ports 229 may be exposed to an external environment through one or more holes formed in the first housing 210 and/or the second housing 220. In an embodiment, the holes formed in the first housing 210 and/or the second housing 220 may be commonly used for the input devices 215 and the sound output devices 227 and 228. In an embodiment, the sound output devices 227 and 228 may include a speaker that operates without holes formed in the first housing 210 and/or the second housing 220 (e.g., a piezo speaker).

According to an embodiment, the camera modules 216a, 216b, and 225 may include a first camera module 216a disposed on the first surface 211 of the first housing 210, a second camera module 216b disposed on the second surface 212 of the first housing 210, and/or a third camera module 225 disposed on the fourth surface 222 of the second housing 220.

According to an embodiment, the electronic device 200 may include a flash 218 located near the second camera module 216b. According to an embodiment, the flash 218 may include, for example, a light-emitting diode or a xenon lamp.

According to an embodiment, the camera modules 216a, 216b, and 225 may include one or more lenses, an image sensor, and/or an image signal processor. In an embodiment, at least one of the camera modules 216a, 216b, and 225 may include two or more lenses (e.g., wide-angle and telephoto lenses) and image sensors, and the camera modules may be disposed together on one surface of the first housing 210 and/or the second housing 220.

According to an embodiment, the sensor modules 217a, 217b, and 226 (e.g., the sensor module 176 of FIG. 1) may generate an electrical signal or a data value corresponding to an operating state of the inside of the electronic device 200 or an external environment state.

According to an embodiment, the sensor modules 217a, 217b, and 226 (e.g., the sensor module 176 of FIG. 1) may include a first sensor module 217a disposed on the first surface 211 of the first housing 210, a second sensor module 217b disposed on the second surface 212 of the first housing 210, and/or a third sensor module 226 disposed on the fourth surface 222 of the second housing 220.

In an embodiment, the sensor modules 217a, 217b, and 226 (e.g., the sensor module 176 of FIG. 1) may include at least one of a gesture sensor, a gyro sensor, a grip sensor, a color sensor, an infrared (IR) sensor, an illuminance sensor, an ultrasonic sensor, a proximity sensor, a biometric sensor (e.g., an iris recognition sensor), a distance detection sensor (e.g., a time-of-flight (TOF) sensor, a light detection and ranging (LiDAR) sensor), a pressure sensor, a magnetic sensor (e.g., a 6-axis sensor, a geomagnetic sensor), an acceleration sensor, a temperature sensor, a humidity sensor, and/or a fingerprint recognition sensor.

According to an embodiment, a processor (e.g., the processor 120 of FIG. 1) of the electronic device 200 may operate the sensor modules 217a, 217b, and 226 (e.g., the sensor module 176 of FIG. 1) to detect illuminance and/or IR intensity around the electronic device 200. The processor 120 may acquire information regarding the illuminance and the IR intensity around the electronic device 200.

According to an embodiment, the electronic device 200 may include at least one of a gesture sensor, a gyro sensor, a grip sensor, a color sensor, an infrared (IR) sensor, an illuminance sensor, an ultrasonic sensor, a proximity sensor, a biometric sensor (e.g., an iris recognition sensor), a distance detection sensor (e.g., a time of flight (TOF) sensor, a light detection and ranging (LiDAR) sensor), a pressure sensor, a magnetic sensor (e.g., a 6-axis sensor, a geomagnetic sensor), an acceleration sensor, a temperature sensor, a humidity sensor, and/or a fingerprint recognition sensor, which are not illustrated.

In an embodiment, the fingerprint recognition sensor may be disposed on at least one of the first side surface member 213 of the first housing 210 and the second side surface member 223 of the second housing 220.

According to an embodiment, the key input devices 219 may be disposed to be exposed to the outside through the first side surface member 213 of the first housing 210. In an embodiment, the key input devices 219 may be disposed to be exposed to the outside through the second side surface member 223 of the second housing 220. In an embodiment, the electronic device 200 may not include some or all of the above-mentioned key input devices 219, and a key input device 219, which is not included, may be implemented in another form, such as a soft key, on at least one display 230 or 235. As an embodiment, the key input devices 219 may be implemented using a pressure sensor included in the at least one display 230 or 235.

According to an embodiment, the connector port 229 may include a connector (e.g., a USB connector or an interface connector port module (IF module)) configured to transmit/receive power and/or data to/from an external electronic device. In an embodiment, the connector ports 229 may be configured to perform a function for transmitting/receiving an audio signal to and from the external electronic device, or may further include a separate connector port (e.g., an ear jack hole) configured to perform an audio signal transmitting/receiving function.

According to an embodiment, at least one camera module 216a or 225 among the camera modules 216a, 216b, and 225, at least one sensor module 217a or 226 among the sensor modules 217a, 217b, and 226, and/or an indicator may be disposed to be visually exposed through the at least one display 230 or 235. For example, at least one camera module 216a or 225, at least one sensor module 217a or 226, and/or an indicator may be disposed under an active region (display region) of at least one display 230 or 235 in an internal space of at least one housing 210 or 220. At least one camera module 216a or 225, at least one sensor module 217a or 226, and/or an indicator may be disposed so as to be in contact with an external environment through an opening or a transparent region formed in a cover member (e.g., a window layer (not illustrated) of the first display 230 and/or the second rear surface cover 250).

According to an embodiment, a region in which the at least one display 230 or 235 and the at least one camera module 216a or 225 face each other may be provided as a transmissive region with a predetermined transmittance, as a portion of a content display region.

According to an embodiment, the transmissive region may have a transmittance ranging from about 5% to about 20%. The transmissive region may include a region overlapping the effective region (e.g., a field-of-view angle region) of the at least one camera module 216a or 225 through which light passes to be imaged by an image sensor to generate an image. For example, the transmissive region of the display 230 or 235 may include a region having a lower pixel density than the periphery. For example, the transmissive region may replace the opening. For example, the at least one camera module 216a or 225 may include an under-display camera (UDC) or an under-panel camera (UPC). As an embodiment, some camera modules or sensor modules 217a and 226 may be disposed to perform the functions thereof without being visually exposed through a display. For example, the regions facing the camera modules 216a and 225 and/or the sensor modules 217a and 226 disposed under the displays 230 and 235 (e.g., a display panel) may have an under-display camera (UDC) structure, and may not require a perforated opening.

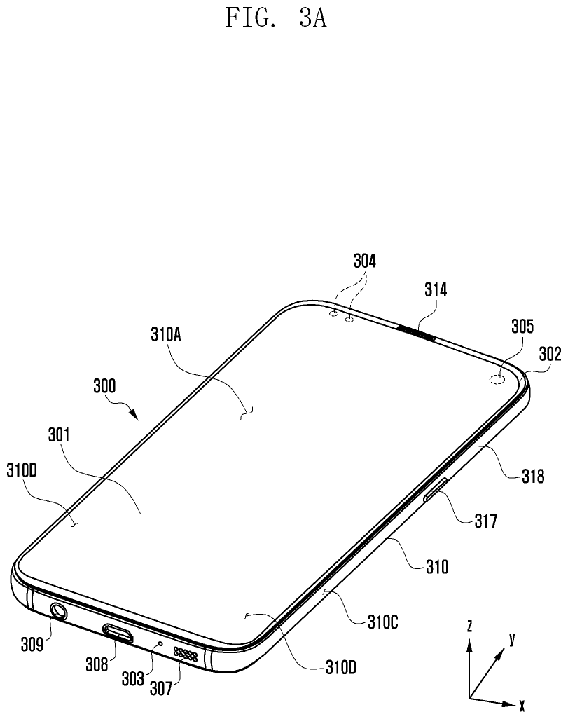

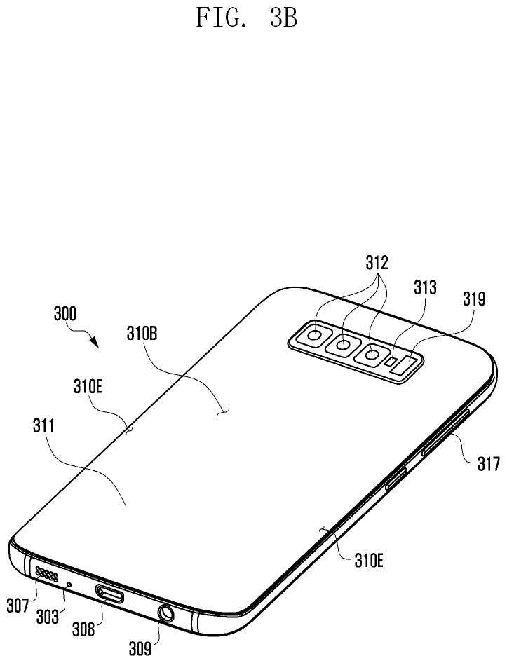

FIG. 3A is a front perspective view of an example electronic device illustrating a first surface (e.g., the front surface) according to various embodiments. FIG. 3B is a rear perspective view of the electronic device illustrating a second surface (e.g., the rear surface) according to various embodiments.

Referring to FIGS. 3A and 3B, an electronic device 300 (e.g., the electronic device 101 of FIG. 1, or the electronic device 400 of FIG. 4) according to an embodiment of the disclosure may include a first surface (or front surface) 310A, a second surface (or rear surface) 310B, and a housing 310. The electronic device 300 according to an embodiment of the disclosure (e.g., the electronic device 101 of FIG. 1, the electronic device 400 of FIG. 4) may include a display 301 (e.g., the display 410 of FIG. 4).

According to an embodiment, the display 301 may be supported by the housing 310. For example, the display 301 may include a liquid crystal display (LCD) display, an organic light-emitting diode (OLED) display, or a micro light-emitting diode (micro-LED) display.

According to an embodiment, the housing 310 may include a side surface 310C surrounding a space between the first surface 310A and the second surface 310B. According to an embodiment, the housing 310 may also refer to a structure that at least partially forms the first surface 310A, the second surface 310B, and the side surface 310C.

According to an embodiment, at least a portion of the first surface 310A may be defined by a substantially transparent front surface plate 302 (e.g., a glass plate or a polymer plate including various coating layers).

According to an embodiment, the second surface 310B may be defined by a substantially opaque rear surface plate 311. The rear surface plate 311 may be made of, for example, coated or colored glass, ceramic, polymer, metal (e.g., aluminum, stainless steel (STS), or magnesium), or a combination of two or more of these materials. However, the disclosure is not limited thereto, and the rear surface plate 311 may be formed of transparent glass.

According to an embodiment, the side surface 310C may be defined by a side surface bezel structure 318 (or a “side surface member”) coupled to the front surface plate 302 and the rear surface plate 311 and including metal and/or polymer. According to an embodiment, the rear surface plate 311 and the side surface bezel structure 318 may be integrated with each other and may include the same material (e.g., a metal material such as aluminum).

According to an embodiment, the front surface plate 302 may include two first regions 310D that are curved from the first surface 310A toward the rear surface plate 311 and extend seamlessly. The two first regions 310D may be disposed at opposite long edge ends of the front surface plate 302.

According to an embodiment, the rear surface plate 311 may include two second regions 310E that are curved from the second surface 310B toward the front surface plate 302 and extend seamlessly.

According to an embodiment, the front surface plate 302 (or the rear surface plate 311) may include only one of the first regions 310D (or the second regions 310E). According to an embodiment, some of the first regions 310D or the second regions 310E may not be included.

In various embodiments, when viewed from a side of the electronic device 300, the side surface bezel structure 318 may have a first thickness (or width) at a side where the first regions 310D or the second regions 310E as described above are not included. In various embodiments, when viewed from a side of the electronic device 300, the side surface bezel structure 318 may have a second thickness (or width) smaller than the first thickness at a side surfaces where the first regions 310D or the second regions 310E are included.

According to an embodiment, the electronic device 300 may include at least one of a display 301, an sound input device 303 (e.g., the input module 150 of FIG. 1, a microphone), sound output devices 307 and 314 (e.g., the sound output module 155 of FIG. 1 or a speaker) (e.g., an audio module), sensor modules 304 and 319 (e.g., the sensor module 176 of FIG. 1), camera modules 305 and 312 (e.g., the camera module 180 of FIG. 1), a flash 313, key input devices 317, an indicator (not illustrated), and connectors 308 and 309. According to an embodiment, the electronic device 300 may omit at least one of the components (e.g., the key input devices 317) or additionally include other components.

According to an embodiment, the display 301 may be visible through an upper end portion of the front surface plate 302.

According to an embodiment, at least a portion of the display 301 may be visible through the front surface plate 302 that forms the first surface 310A and the first regions 310D of the side surface 310C.

For example, the display module (e.g., the display module 160 of FIG. 1 or the display module 160 of FIG. 4) may include a touch circuit (e.g., the touch circuit 450 of FIG. 4) that includes a touch sensor (e.g., the touch sensor 451 of FIG. 4) and a touch sensor IC (e.g., the touch sensor IC 453 of FIG. 4). The display module (e.g., the display module 160 of FIG. 1, the display module 160 of FIG. 4) may include a pressure sensor capable of measuring the intensity (pressure) of a touch. For example, the display 301 may be coupled with or disposed adjacent to a touch circuit (e.g., the touch circuit 450 of FIG. 4) and/or a pressure sensor. For example, the display 301 may be coupled to or disposed adjacent to a digitizer (e.g., the digitizer 460 in FIG. 4) configured to detect a magnetic field-type electronic pen (e.g., a stylus pen).

According to an embodiment, at least some of the sensor modules 304 and 319, and/or at least some of the key input devices 317 may be disposed in the first region 310D and/or the second region 310E.

According to an embodiment, at least one of the first sensor module 304, the camera modules 305 and 312 (e.g., image sensors), the sound output device 314 (e.g., an audio module), and a fingerprint sensor may be provided on the rear surface of a screen display region of the display 301.

According to an embodiment, at least some of the sensor modules 304 and 319 and/or some of the key input device 317 may be disposed in the first regions 310D and/or the second regions 310E.

According to an embodiment, the sound input device 303 may include a microphone. According to an embodiment, the input device 303 may include a plurality of microphones arranged to detect the direction of sound.

According to an embodiment, the sound output devices 307 and 314 may include a sound output device 307 operating as an external speaker and a sound output device 314 operating as a call receiver.

In various embodiments, the sound input device 303 (e.g., a microphone), the sound output devices 307 and 314, and the connectors 308 and 309 may be disposed in an internal space of the electronic device 300. The sound input device 303 (e.g., a microphone), the sound output devices 307 and 314, and the connectors 308 and 309 may be exposed to an external environment through at least one hole formed in the housing 310. In various embodiments, the hole formed in the housing 310 may be commonly used for the sound input device 303 (e.g., a microphone) and the sound output devices 307 and 314. According to various embodiments, the sound output devices 307 and 314 may include a speaker that operates without a separate speaker hole provided in the housing 310 (e.g., a piezo speaker).

According to an embodiment, the sensor modules 304 and 319 (e.g., the sensor module 176 in FIG. 1) may generate an electrical signal or a data value corresponding to the internal operating state or the external environmental state of the electronic device 300. The sensor modules 304 and 319 may include a first sensor module 304 (e.g., a proximity sensor) arranged on the first surface 310A of the housing 310, a second sensor module 319 (e.g., an HRM sensor) arranged on the second surface 310B of the housing 310, and/or a third sensor module (not illustrated) (e.g., a fingerprint sensor). For example, the fingerprint sensor may be arranged on the first surface 310A (e.g., the display 301) and/or the second surface 310B of the housing 310.

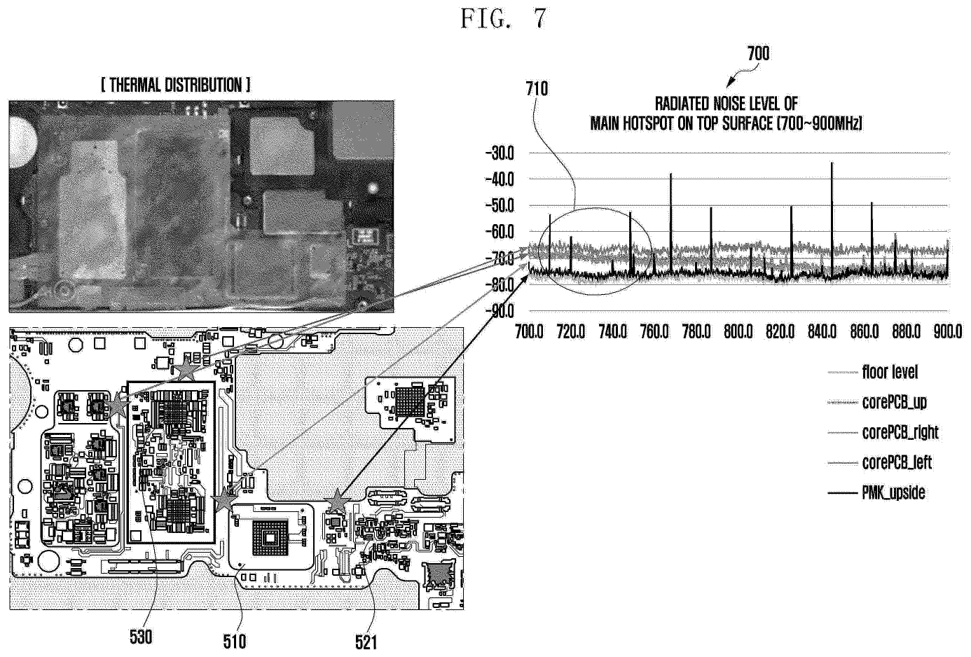

The electronic device 300 may further include at least one of a gesture sensor, a gyroscope sensor, a pressure sensor, a magnetic sensor (e.g., the geomagnetic sensor 700 of FIG. 7), an acceleration sensor, a grip sensor, a color sensor, an infrared (IR) sensor, a biometric sensor, a temperature sensor, a humidity sensor, and/or an illuminance sensor (not illustrated).

According to an embodiment, the camera modules 305 and 312 may include a first camera module 305 arranged on the first surface 310A of the electronic device 300, and a second camera module 312 arranged on the second surface 310B of the electronic device 200. A flash 313 may be disposed around the camera modules 305 and 312. The camera modules 305 and 312 may include one or more lenses, an image sensor, and/or an image signal processor. The flash 313 may include, for example, a light-emitting diode or a xenon lamp.

According to an embodiment, the first camera module 305 may be arranged under the display panel of the display 301 in a manner of an under-display camera (UDC). According to an embodiment, two or more lenses (a wide-angle lens and a telephoto lens) and image sensors may be arranged on one surface of the electronic device 300. According to an embodiment, a plurality of first camera modules 305 may be disposed on the first surface of the electronic device 300 (e.g., the surface on which a screen is to be displayed) in an under-display camera (UDC) manner.

According to an embodiment, key input devices 317 may be disposed on the side surface 310C of the housing 310. According to an embodiment, the electronic device 300 may not include some or all of the above-described key input devices 317, and a key input device 317 not included may be implemented in another form, such as a soft key, on the display 301. According to an embodiment, the key input devices 317 may be implemented using pressure sensors included in the display 301.

According to an embodiment, the connectors 308 and 309 may include a first connector hole 308 capable of accommodating a connector (e.g., a USB connector) configured to transmit/receive power and/or data to/from an external electronic device, and/or a second connector hole 309 (or an earphone jack) capable of accommodating a connector configured to transmit/receive audio signals to/from an external electronic device. The first connector hole 308 may include a universal serial bus (USB) A type, a USB B type, or a USB C type port. When the first connector hole 308 supports the USB C type, the electronic device 300 (e.g., the electronic device 101 of FIG. 1, the electronic device 200 of FIG. 2A, or the electronic device 400 of FIG. 4) may support USB power delivery (PD) charging.

According to an embodiment, a first camera module 305 among the camera modules 305 and 312 and/or a first sensor module 304 among the sensor modules 304 and 319 may be disposed to be visually exposed through the display 301.

According to an embodiment, when the first camera module 305 is disposed in an under display camera (UDC) manner, the first camera module 305 may not be visually exposed to the outside.

According to an embodiment, the first camera module 305 may be disposed to overlap the display region, and a screen may be displayed even in a display region corresponding to the first camera module 305. The first sensor module 304 may be disposed in the internal space of the electronic device 300 so as to perform its function without being visually exposed through the front surface plate 302.

FIG. 4 is a block diagram illustrating an example configuration of an electronic device according to various embodiments.

Referring to FIG. 4, an electronic device 400 according to an embodiment of the disclosure may include a processor (e.g., including processing circuitry) 120 (e.g., the processor 120 of FIG. 1), a memory 130 (e.g., the memory 130 of FIG. 1), a sensor module (e.g., including at least one sensor) 176, and a display module (e.g., including at least one display) 160 (e.g., the display module 160 of FIG. 1).

In an embodiment, the memory 130 (e.g., the memory 130 of FIG. 1 or the memory 130 of FIG. 4) may include one or more of high bandwidth memory (HBM), dynamic random access memory (DRAM), static random access memory (SRAM), phase-change random access memory (PRAM), magnetic random access memory (MRAM), resistive random access memory (RRAM), flash memory, and/or electrically erasable programmable read-only memory (EEPROM).

According to an embodiment, the display module 160 (e.g., the display module 160 of FIG. 1) may include a display 410, a display driver IC (DDIC) 430 (e.g., a display driver) configured to drive the display 410, a touch circuit 450, a digitizer 460, and a digitizer driver 470. For example, the sensor module 176 may be entirely or partially included in the display module 160.

According to an embodiment, the DDIC 430 may include an interface module 431 (e.g., an interface circuit), a memory 433 (e.g., a buffer memory), an image processing module 435 (e.g., an image processing circuit), or a mapping module 437 (e.g., a mapping circuit).

According to an embodiment, the DDIC 430 may receive image information including image data or image control signals corresponding to a command for controlling the image data through the interface module 431 from another component of the electronic device (e.g., the electronic device 101 of FIG. 1, or the electronic device 200 of FIGS. 2 and 3).

According to an embodiment, the image information may be received from a processor (e.g., the processor 120 in FIG. 1) (e.g., the main processor 121 in FIG. 1) (e.g., an application processor), or an auxiliary processor (e.g., the auxiliary processor 123 in FIG. 1) (e.g., a graphics processor) operated independently from the function of the main processor 121.

According to an embodiment, the DDIC 430 may communicate with the touch circuit 450 or the sensor module 176 through the interface module 431. In addition, the DDIC 430 may store at least a part of the received image information in the memory 433. As an example, the DDIC 430 may store at least a portion of the received image information in the memory 433 in frame units.

According to an embodiment, the image processing module 435 may include various circuitry and/or executable program instructions and perform pre-processing or post-processing (e.g., adjustment of resolution, brightness, or size) on at least a part of the image data based at least on characteristics of the video data or the characteristics of the display 410.

According to an embodiment, the mapping module 437 may include various circuitry and/or executable program instructions and generate a voltage value or a current value corresponding to the image data preprocessed or post-processed by the image processing module 435. According to an embodiment, the generation of a voltage value or a current value may be at least partially based on, for example, attributes (e.g., an arrangement of pixels (RGB stripe or pentile structure), or sizes of respective sub-pixels) of the pixels of the display 410.

According to an embodiment, at least some of the pixels of the display 410 may be driven based at least in part on a voltage value or a current value so as to display, through the display 410, visual information (e.g., text, images, or icons) corresponding to the image data.

According to an embodiment, the touch circuit 450 may include a touch sensor 451 and a touch sensor IC 453 configured to control the touch sensor 451.

According to an embodiment, the touch sensor IC 453 may control the touch sensor 451 to detect a touch input or a hovering input at a specific position of the display 410. For example, the touch sensor IC 453 may detect a touch input or a hovering input by measuring a change in a signal (e.g., voltage, light amount, resistance, or charge amount) with respect to a specific position in the display 410. The touch sensor IC 453 may provide information on the detected touch input or hovering input (e.g., position, area, pressure, or time) to the processor 120.

According to an embodiment, at least a part of the touch circuit 450 (e.g., the touch sensor IC 453) may be included as a part of the DDIC 430 or the display 410.

According to an embodiment, at least a part of the touch circuit 450 (e.g., the touch sensor IC 453) may be included as a part of another component (e.g., the auxiliary processor 123) disposed outside the display module 160.

According to an embodiment, the display module 160 may further include at least one sensor (e.g., a fingerprint sensor, an iris sensor, a pressure sensor, or a light sensor) of the sensor module 176 or a control circuit therefor. In this case, the at least one sensor or a control circuitry for the same may be embedded in a part of the display module 160 (e.g., the display 410 or the DDIC 430) or a part of touch circuit 450.

For example, when the sensor module 176 embedded in the display module 160 includes a biometric sensor (e.g., a fingerprint sensor), the biometric sensor may acquire biometric information (e.g., a fingerprint image) associated with a touch input through a portion of the display 410.

For example, when the sensor module 176 embedded in the display module 160 includes a pressure sensor, the pressure sensor may acquire pressure information associated with a touch input through a portion or the entire region of the display 410.

According to an embodiment, the touch sensor 451 or the sensor module 176 may be arranged between pixels of the pixel layer of the display 410, or above or below the pixel layer.

According to an embodiment, the display module 160 may include a digitizer 460 configured to detect input (e.g., a touch input or a hovering input) from an electronic pen (e.g., a stylus pen). For example, the digitizer 460 may convert analog coordinates (e.g., a position) of an electronic pen (e.g., a stylus pen) into digital coordinate data. The digitizer 460 may transmit digital coordinate data to the processor 120 and/or the DDIC 430.

According to an embodiment, the processor 120 may include various processing circuitry and acquire digital coordinate data input from the digitizer 460. The processor 120 may detect an input (e.g., a touch input or a hovering input) through an electronic pen (e.g., a stylus pen) based on the digital coordinate data. For example, the digitizer 460 may include a plurality of x-axis channels and a plurality of y-axis channels. The processor 120 may detect the position of an electronic pen (e.g., a stylus pen) using sensing signals (e.g., EMR signals) received from the x-axis channels and y-axis channels disposed in the digitizer 460. For example, the digitizer 460 may include a plurality of x-axis channels and a plurality of y-axis channels, which are sequentially arranged, and the processor 120 may detect the position of an electronic pen (e.g., a stylus pen) using sensing signals (e.g., EMR signals) received from three consecutive channels (e.g., three adjacent channels).

According to an embodiment, the digitizer 460 may be invisible from the outside due to the display 410, electronic components, and mechanical components.

For example, the digitizer 460 may be disposed integrally with a flat-type display 410, or may be disposed adjacent to the flat-type display 410. For example, when the digitizer 460 is applied to the flat-type display 410, the digitizer 460 may include a single electro magnetic resonance (EMR) sheet (or EMR film). The single EMR sheet may include a plurality of x-axis channels and a plurality of y-axis channels which are configured to detect the position of an electronic pen (e.g., a stylus pen).

For example, the digitizer 460 may be integrally disposed with a flexible display or a foldable display, or may be disposed adjacent to the flexible display or the foldable display. For example, the digitizer 460 may be disposed below (e.g., at the lower side) of the display 410 (e.g., the display 201 of FIGS. 2 and 3) in the z-axis direction (e.g., the z-axis direction of FIGS. 2A and 2B).

For example, when the digitizer 460 is applied to a flexible display or a foldable display, the digitizer 460 may include a plurality of electro-magnetic resonance (EMR) sheets (or EMR films). A plurality of x-axis channels and a plurality of y-axis channels, which are configured to detect the position of an electronic pen (e.g., a stylus pen), may be disposed on the plurality of EMR sheets.

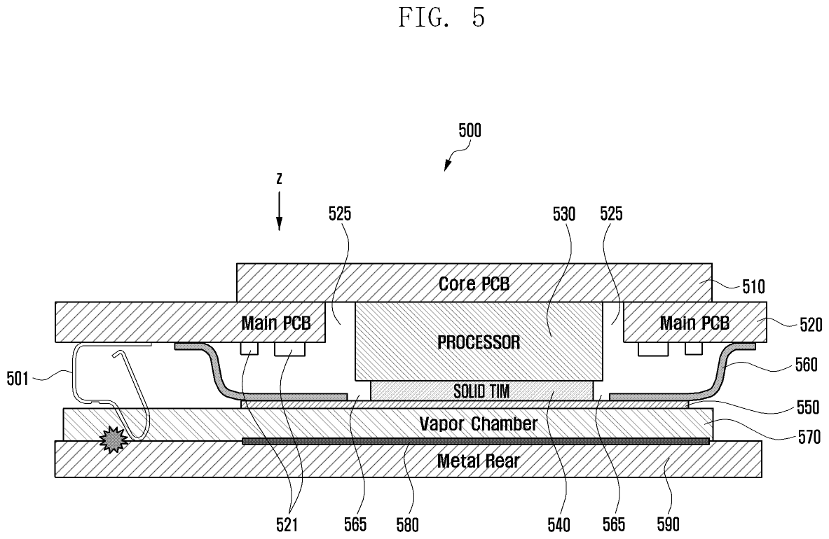

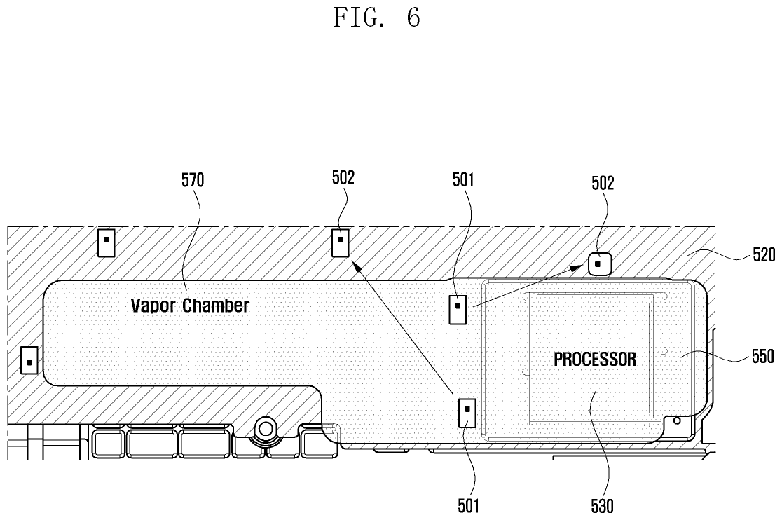

FIG. 5 is a cross-sectional view illustrating an example electronic device in which a ground path is formed between a main PCB and a vapor chamber using a C-clip according to various embodiments. FIG. 6 is a diagram illustrating an example of how a C-clip is electrically connected to a main PCB according to various embodiments.

Referring to FIGS. 5 and 6, the electronic device 500 may include a display module (e.g., the display module 160 of FIG. 4), a first PCB 520 (e.g., a main PCB, a main circuit board), a second PCB 510 (e.g., a processor PCB, a core circuit board), a processor 530 (e.g., an application processor (AP), a central processing unit (CPU)), electronic components 521, a heat dissipation member 540 (e.g., a heat dissipation component, a solid thermal interface material (TIM), a heat-spreading (heat-conducting) member, thermal grease, a heat dissipation paste, a heat-spreading (heat-conducting) paste), a shielding member 550 (e.g., a shield component, a metal TIM, a shield plate, a metal heat dissipation member, a metal heat dissipation plate), a shield can 560, a vapor chamber 570, a conductive member 580 (e.g., a conductive double-sided tape, a conductive adhesive layer), a conductive plate 590 (e.g., a metal rear, a metal plate), and a conductive clip 501 (e.g., a C-clip, a conductive contact member).

According to an embodiment, a display module (e.g., the display module 160 of FIG. 4) may be disposed on the first PCB 520 (e.g., a main PCB, a main circuit board). The display module 160 may include a display (e.g., the display 410 of FIG. 4), a touch circuit 450, and a digitizer 460.

According to an embodiment, when the electronic device 500 (or the display 410) is viewed in a first direction (e.g., the z-axis direction, a vertical direction), the conductive plate 590 (e.g., a metal rear) may be disposed to face the display 410. Components (e.g., parts) configured to shield noise (e.g., electromagnetic waves) and to dissipate heat (e.g., thermal cooling, heat release) may be disposed between the conductive plate 590 (e.g., a metal rear, a metal plate) and the display 410.

According to an embodiment, in order to shield noise (e.g., electromagnetic waves) generated from the processor 530 and the electronic components 521 and to dissipate heat (e.g., thermal cooling, heat release), a shielding member 550, a shield can 560, and a vapor chamber 570 may be disposed.

According to an embodiment, the vapor chamber 570 may be disposed on the conductive plate 590 (e.g., a metal rear). For example, when the electronic device 500 (or the display 410) is viewed in a first direction (e.g., the z-axis direction or a vertical direction), the conductive member 580 (e.g., a conductive double-sided tape, a conductive adhesive layer) may be disposed between the conductive plate 590 (e.g., a metal rear, a metal plate) and the vapor chamber 570. For example, the conductive member 580 (e.g., a conductive double-sided tape, a conductive adhesive layer) may electrically connect (e.g., electrically attach) the conductive plate 590 (e.g., a metal rear, a metal plate) and the vapor chamber 570.

According to an embodiment, the shielding member 550 (e.g., a shield component, a metal TIM, a shield plate, a metal heat dissipation member, a metal heat dissipation plate) may be disposed on the vapor chamber 570.

For example, the shielding member 550 may include a material (e.g., metal) or an alloy (e.g., CuSi) having high electrical and thermal conductivity. For example, the shielding member 550 may include a material having high thermal conductivity, such as stainless steel, copper (Cu), nickel (Ni), silver (Ag), gold (Au), silicon (Si), or aluminum (Al). For example, the shielding member 550 may include a composite material including a thermally conductive filler or a polymer.

For example, the shielding member 550 may be disposed to face (e.g., overlap) the processor 530 and the electronic components 521 which generate heat.

According to an embodiment, the heat dissipation member 540 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member 550 to at least partially overlap the shielding member 550.

According to an embodiment, at least a portion of the first PCB 520 (e.g., a main PCB, a main circuit board) and at least a portion of the second PCB 510 (e.g., a processor PCB, a core circuit board) may be disposed to overlap each other. The first PCB 520 (e.g., a main PCB, a main circuit board) may include a first opening 525. The processor 530 may be disposed on the second PCB 510 (e.g., a processor PCB, a core circuit board) by the first opening 525. For example, the first PCB 520 (e.g., a main PCB, a main circuit board) may have electronic components 521 and peripheral circuits disposed thereon. For example, the electronic components 521 may include a communication module (e.g., the communication module 190 of FIG. 1), and/or a controller.

According to an embodiment, the processor 530 and core circuits may be disposed on the second PCB 510 (e.g., a processor PCB, a core circuit board). For example, the core circuits may include a power management integrated circuit (PMIC) (e.g., the power management module 188 of FIG. 1).

According to an embodiment, the processor 530 (e.g., the processor 120 of FIG. 1, the processor 120 of FIG. 4) may include one or more of an application processor (AP), a central processing unit (CPU), a graphics processing device (e.g., a mobile graphics processing unit (GPU), a central processor (CP), an image signal processor, a communication processor, and a sensor hub processor.

In an embodiment, the memory (e.g., the memory 130 of FIG. 1 or the memory 130 of FIG. 4) may include one or more of high bandwidth memory (HBM), dynamic random access memory (DRAM), static random access memory (SRAM), phase-change random access memory (PRAM), magnetic random access memory (MRAM), resistive random access memory (RRAM), flash memory, and/or electrically erasable programmable read-only memory (EEPROM).

For example, the processor 530 may be disposed on the second PCB 510 (e.g., a processor PCB, a core circuit board) so as to be positioned within the first opening 525. For example, the first PCB 520 (e.g., a main PCB, a main circuit board) and the second PCB 510 (e.g., a processor PCB, a core circuit board) may be electrically connected (e.g., directly or indirectly).

According to an embodiment, the memory (e.g., the memory 130 of FIG. 1, the memory 130 of FIG. 4) may be disposed on the first PCB 520 and/or the second PCB 510 (e.g., a processor PCB, a core circuit board).

According to an embodiment, the shield can 560 may include a second opening 565. The shield can 560 may be disposed on the first PCB 520 (e.g., a main PCB, a main circuit board) so as to surround the peripheral portion of the electronic components 521.

For example, the shield can 560 may be disposed to cover at least a portion of the first PCB 520 (e.g., a main PCB, a main circuit board) and at least a portion of the second PCB 510 (e.g., a processor PCB, a core circuit board). For example, the shield can 560 may be disposed to cover the electronic components 521 disposed on the first PCB 520 (e.g., a main PCB, a main circuit board) and the processor 530 disposed on the second PCB 510 (e.g., a processor PCB, a core circuit board). For example, the shield can 560 may have not only a heat dissipation function but also an electromagnetic interference (EMI) shielding function.

According to an embodiment, the heat dissipation member 540 (e.g., a heat dissipation component, a solid thermal interface material (TIM), a heat-shielding (heat-conducting) member, thermal grease, a heat dissipation paste, a heat-spreading (heat-conducting) paste) may be disposed between the processor 530 and the shielding member 550.

For example, the heat dissipation member 540 may be disposed to face (e.g., overlap) the processor 530 so as to release (e.g., cool or diffuse) heat generated by the processor 530. For example, the shielding member 550 may be disposed to face (e.g., overlap) the electronic components 521 and the processor 530, so as to release (e.g., cool or diffuse) heat generated from the electronic components 521 and the processor 530. For example, the shielding member 550 may be disposed to cover (e.g., to seal) the second opening 565 of the shield can 560. For example, the shielding member 550 may have not only a heat dissipation function, but also an electromagnetic interference (EMI) shielding function.

According to an embodiment, when the electronic device 500 (or the display 410) is viewed in the first direction (e.g., the z-axis direction or a vertical direction), the vapor chamber 570 may be disposed between the conductive plate 590 (e.g., a metal rear, a metal plate) and the shielding member 550.

According to an embodiment, the conductive clip 501 (e.g., a C-clip, a conductive contact member) may be disposed between the first PCB 520 (e.g., a main PCB, a main circuit board) and the vapor chamber 570. For example, the conductive clip 501 (e.g., a C-clip, a conductive contact member) may electrically connect the first PCB 520 (e.g., a main PCB, a main circuit board) and the vapor chamber 570.

FIG. 7 is a diagram including a graph 700 illustrating noise and heat generated from a core PCB on which a processor is disposed according to various embodiments.

Referring to FIG. 7, noise 710 (e.g., electromagnetic waves) may be generated from a processor 530 and electronic components 521. Since a large amount of noise 710 (e.g., electromagnetic waves) is generated in a second PCB 510 (e.g., a processor PCB, a core circuit board) on which the processor 530 is disposed, it is necessary to form a ground path for shielding (e.g., removing) the noise 710 (e.g., the electromagnetic waves). For example, a ground path may be formed between a first PCB 520 (e.g., a main PCB, a main circuit board) and a vapor chamber 570 using a conductive clip 501 (e.g., a C-clip, a conductive contact member). For example, a ground path may be formed around the processor 530 using a plurality of conductive clips 501 (e.g., C-clips, conductive contact members) (e.g., 10 conductive clips).

For example, as the contact of a ground path using a conductive clip 501 (e.g., a C-clip, a conductive contact member) is located closer to the position of a component that generates noise (e.g., electromagnetic waves), the shielding (or removal) effect may increase. As the contact of the ground path using the conductive clip 501 (e.g., a C-clip, a conductive contact member) is located farther from the position of the component that generates noise (e.g., electromagnetic waves), the shielding (or removal) effect may decrease. In order to enhance the shielding (or removal) effect of noise (e.g., electromagnetic waves) generated from the processor 530, it is necessary to dispose the conductive clip 501 (e.g., a C-clip, a conductive contact member) at a position adjacent to the processor 530. However, the area of the second PCB 510 (e.g., a processor PCB, a core circuit board) may be smaller than that of the first PCB 520 (e.g., a main PCB, a main circuit board) (e.g., the second PCB may have an area that is about 10% of the area of the first PCB). There is a limitation in forming a ground path using the conductive clip 501 (e.g., a C-clip, a conductive contact member) in the second PCB 510 (e.g., a processor PCB, a core circuit board). As a result, a position where the conductive clip 501 (e.g., a C-clip, a conductive contact member) is disposed may be moved to a region 502 of the first PCB 520 (e.g., a main PCB, a main circuit board).

For example, a portion of the vapor chamber 570 may be removed, and the second PCB 510 (e.g., a processor PCB, a core circuit board) and the conductive plate 590 (e.g., a metal rear) may be electrically connected by the conductive clip 501 (e.g., a C-clip, a conductive contact member). In this case, the area of the vapor chamber 570 may be reduced, which may degrade heat dissipation performance. As a result, the position where the conductive clip 501 (e.g., a C-clip, a conductive contact member) is disposed may be moved to a region 502 of the first PCB 520 (e.g., a main PCB, a main circuit board) to form a ground path contact with the conductive clip 501 (e.g., a C-clip, a conductive contact member).

TABLE 1
Performance variation depending on whether shield
can chamber contact structure is applied

| BAND | 28 | 20 | 5 | 8 | 3 | 1 | 7 | 2 | 4 | 66 |
|---|---|---|---|---|---|---|---|---|---|---|
| AP OFF | 97.7 | 97.7 | 95.8 | 95.65 | 96.1 | 95 | 96.2 | 94 | 96.2 | 95.3 |
| Basic State | | | | | | | | | | |
| Comparative Exam. | 92.3 | 91.9 | 91.8 | 92.1 | 92.7 | 94.3 | 95.3 | 92.7 | 94.4 | 93.8 |
| Structure | −5.4 | −5.8 | −3 | −2.55 | −3.4 | −0.7 | −0.9 | −1.3 | −1.8 | −1.5 |
| AP ON Spec. [−3 dB] | | | | | | | | | | |

When the shield can 560, the shielding member 550, and the conductive clip 501 (e.g., a C-clip, a conductive contact member) are applied to the electronic device 500 for various frequency bands (e.g., LTE bands 28, 20, 5, 8, 3, 17, 2, 4, and 66), the noise (e.g., electromagnetic waves) shielding (or removal) performance may be improved, as shown in Table 1, by improving total isotropic sensitivity (TIS). The TIS is an indicator representing the performance of the Rx terminal of a wireless device in free space, and the TIS may be improved by applying the shield can 560, the shielding member 550, and the conductive clip 501 (e.g., a C-clip, a conductive contact member).

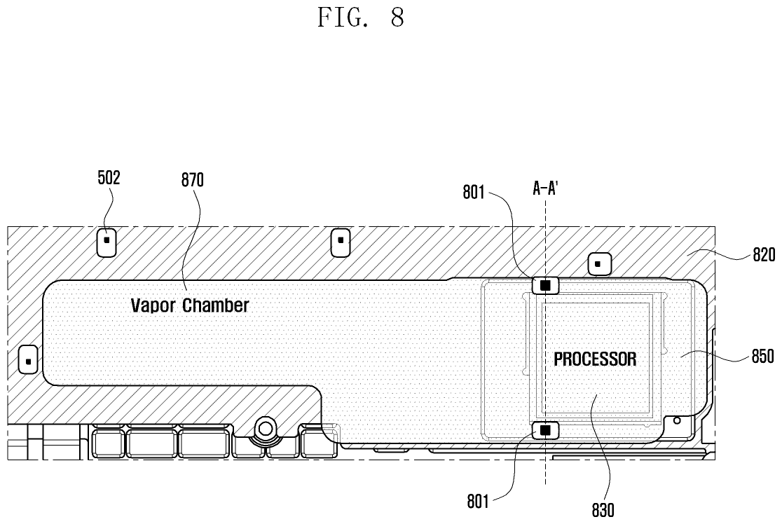

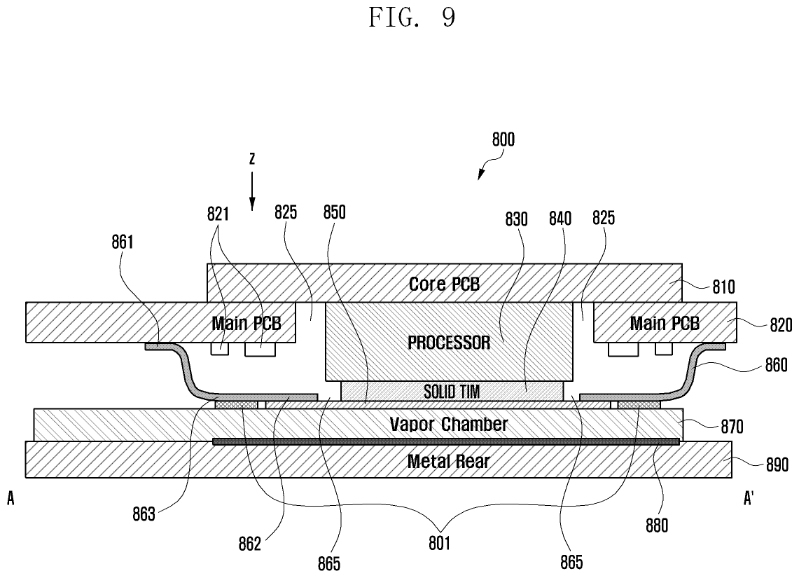

FIGS. 8 and 9 are a diagram and cross-sectional view illustrating an electronic device, which includes a conductive member (e.g., a conductive gasket) electrically connecting a main PCB and a vapor chamber, according to various embodiments.

Referring to FIGS. 8 and 9, an electronic device 800 according to an embodiment of the disclosure may include a display module (e.g., the display module 160 of FIG. 4), a first PCB 820 (e.g., a main PCB, a main circuit board), a second PCB 810 (e.g., a processor PCB, a core circuit board), a processor 830 (e.g., an application processor (AP), a central processing unit (CPU)), electronic components 821, a heat dissipation member 840 (e.g., a heat dissipation component, a solid thermal interface material (TIM), a heat spreading (heat-conducting) member, thermal grease, a heat dissipation paste, a heat spreading (heat-conducting) paste), a shielding member (metal TIM) 850 (e.g., a shielding component, a metal TIM, a shielding plate, a metal heat dissipation member, a metal heat dissipation plate), a shield can 860, a vapor chamber 870, a first conductive member 880 (e.g., a conductive double-sided tape, a conductive adhesive layer), a conductive plate 890 (e.g., a metal rear, a metal plate), and a second conductive member 801 (e.g., a gasket).

According to an embodiment, a display module (e.g., the display module 160 of FIG. 4) may be disposed on the first PCB 820 (e.g., a main PCB, a main circuit board). The display module 160 may include a display (e.g., the display 410 of FIG. 4) and a digitizer 460.

According to an embodiment, when the electronic device 800 (or the display 410) is viewed in a first direction (e.g., the z-axis direction, a vertical direction), the conductive plate 890 (e.g., a metal rear) may be disposed to face the display 410. Components (e.g., parts) configured to shield noise (e.g., electromagnetic waves) and to dissipate heat (e.g., thermal cooling, heat release) may be disposed between the conductive plate 890 (e.g., a metal rear, a metal plate) and the display 410.

According to an embodiment, the shielding member (metal TIM) 850, the shield can 860, the vapor chamber 870, the first conductive member 880 (e.g., a conductive double-sided tape, the conductive adhesive layer), the conductive plate 890 (e.g., a metal rear, a metal plate), and the second conductive member 801 (e.g., a gasket) may be disposed to shield noise (e.g., electromagnetic waves) generated from the processor 830 and the electronic components 821, and to release heat (e.g., thermal cooling, heat dissipation).

According to an embodiment, the vapor chamber 870 may be disposed on the conductive plate 890 (e.g., a metal rear). For example, when the electronic device 800 (or the display 410) is viewed in a first direction (e.g., the z-axis direction or a vertical direction), the first conductive member 880 (e.g., a conductive double-sided tape, a conductive adhesive layer) may be disposed between the conductive plate 890 (e.g., a metal rear, a metal plate) and the vapor chamber 870. For example, the first conductive member 880 (e.g., a conductive double-sided tape, a conductive adhesive layer) may electrically connect (e.g., electrically attach) the conductive plate 890 (e.g., a metal rear, a metal plate) and the vapor chamber 870.

According to an embodiment, the shielding member (metal TIM) 850 (e.g., a shield component, a metal TIM, a shield plate, a metal heat dissipation member, a metal heat dissipation plate) may be disposed on the vapor chamber 870.

For example, the shielding member (metal TIM) 850 may include a material (e.g., metal) or an alloy (e.g., CuSi) having high electrical and thermal conductivity. For example, the shielding member (metal TIM) 850 may include a material having high thermal conductivity, such as stainless steel, copper (Cu), nickel (Ni), silver (Ag), gold (Au), silicon (Si), or aluminum (Al). For example, the shielding member (metal TIM) 850 may include a composite material including a thermally conductive filler or a polymer.

For example, the shielding member (metal TIM) 850 may be disposed to face (e.g., overlap) the processor 830 and the electronic components 821 which generate heat.

According to an embodiment, the heat dissipation member 840 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member (metal TIM) 850 to at least partially overlap the shielding member (metal TIM) 850.

According to an embodiment, the first PCB 820 (e.g., a main PCB, a main circuit board) may include a first opening 825. The processor 830 may be disposed on the second PCB 810 (e.g., a processor PCB, a core circuit board) by the first opening 825. For example, the first PCB 820 (e.g., a main PCB, a main circuit board) may have electronic components 821 and peripheral circuits disposed thereon. For example, the electronic components 821 may include a communication module (e.g., the communication module 190 of FIG. 1), and/or a controller.

According to an embodiment, the processor 830 and core circuits may be disposed on the second PCB 810 (e.g., a processor PCB, a core circuit board). For example, the core circuits may include a power management integrated circuit (PMIC) (e.g., the power management module 188 of FIG. 1).

According to an embodiment, when the electronic device 800 (or the display 410) is viewed in the first direction (e.g., the z-axis direction or a vertical direction), the first PCB 820 (e.g., a main PCB, a main circuit board) may be disposed between the display 410 and the conductive plate 890 (e.g., a metal rear). For example, when the electronic device 800 (or the display 410) is viewed in the first direction (e.g., the z-axis direction, a vertical direction), the first PCB 820 (e.g., a main PCB, a main circuit board) may be disposed between the second PCB 810 (e.g., a processor PCB, a core circuit board) and the vapor chamber 870. For example, when the electronic device 800 (or the display 410) is viewed in the first direction (e.g., the z-axis direction or the vertical direction), the first PCB 820 (e.g., a main PCB, a main circuit board) may be disposed between the second PCB 810 (e.g., a processor PCB, a core circuit board) and the shielding member (metal TIM) 850.

According to an embodiment, when the electronic device 800 (or the display 410) is viewed in the first direction (e.g., the z-axis direction or a vertical direction), the second PCB 810 (e.g., a processor PCB, a core circuit board) may be disposed between the display 410 and the conductive plate 890 (e.g., a metal rear). For example, when the electronic device 800 (or the display 410) is viewed in the first direction (e.g., the z-axis direction or a vertical direction), the second PCB 810 (e.g., a processor PCB, a core circuit board) may be disposed between the display 410 and the vapor chamber 870.

For example, when the electronic device 800 (or the display 410) is viewed in the first direction (e.g., the z-axis direction or a vertical direction), the second PCB 810 (e.g., a processor PCB, a core circuit board) may be disposed between the display 410 and the shielding member (metal TIM) 850.

According to an embodiment, the processor 830 (e.g., the processor 120 of FIG. 1, the processor 120 of FIG. 4) may include one or more of an application processor (AP), a central processing unit (CPU), a graphics processing device (e.g., a mobile graphics processing unit (GPU), a central processor (CP), an image signal processor, a communication processor, and a sensor hub processor.

In an embodiment, the memory (e.g., the memory 130 of FIG. 1 or the memory 130 of FIG. 4) may include one or more of high bandwidth memory (HBM), dynamic random access memory (DRAM), static random access memory (SRAM), phase-change random access memory (PRAM), magnetic random access memory (MRAM), resistive random access memory (RRAM), flash memory, and/or electrically erasable programmable read-only memory (EEPROM).

For example, the processor 830 may be disposed to be positioned within the first opening 825. For example, the first PCB 820 (e.g., a main PCB, a main circuit board) and the second PCB 810 (e.g., a processor PCB, a core circuit board) may be electrically connected (e.g., directly or indirectly). For example, the first PCB 820 (e.g., a main PCB, a main circuit board) and the second PCB 810 (e.g., a processor PCB, a core circuit board) may be electrically connected (e.g., directly or indirectly) through an interposer.

According to an embodiment, the memory (e.g., the memory 130 of FIG. 1, the memory 130 of FIG. 4) may be disposed on the first PCB 820 and/or the second PCB 810 (e.g., a processor PCB, a core circuit board).

According to an embodiment, the shield can 860 may include a second opening 865. The shield can 860 may be disposed on the first PCB 820 (e.g., a main PCB, a main circuit board) so as to surround the peripheral portion of the electronic components 821.

For example, the shield can 860 may be disposed to cover at least a portion of the first PCB 820 (e.g., a main PCB, a main circuit board) and at least a portion of the second PCB 810 (e.g., a processor PCB, a core circuit board). For example, the shield can 860 may be disposed to cover the electronic components 821 disposed on the first PCB 820 (e.g., a main PCB, a main circuit board) and the processor 830 disposed on the second PCB 810 (e.g., a processor PCB, a core circuit board). For example, the shield can 860 may have not only a heat dissipation function but also an electromagnetic interface (EMI) shielding function.

For example, a first shield can portion 861 of the shield can 860 may be electrically connected (e.g., directly or indirectly connected) to the first PCB 820 (e.g., a main PCB or a main circuit board). A second shield can portion 862 of the shield can 860 may be electrically connected to (e.g., directly or indirectly connected to) the shielding member (metal TIM) 850. A third shield can portion 863 of the shield can 860 may be electrically connected (e.g., directly or indirectly connected) to the second conductive member 801 (e.g., a gasket). For example, the third shield can portion 863 of the shield can 860 may be positioned between the first shield can portion 861 and the second shield can portion 862.

According to an embodiment, the heat dissipation member 840 (e.g., a heat dissipation component, a solid thermal interface material (TIM), a heat-shielding (heat-conducting) member, thermal grease, a heat dissipation paste, a heat-spreading (heat-conducting) paste) may be disposed between the processor 830 and the shielding member (metal TIM) 850.

For example, the heat dissipation member 840 may be disposed to face (e.g., overlap) the processor 830 so as to release (e.g., cool or diffuse) heat generated by the processor 830. For example, the shielding member (metal TIM) 850 may be disposed to face (e.g., overlap) the electronic components 821 and the processor 830, so as to release (e.g., cool or diffuse) heat generated from the electronic components 821 and the processor 830. For example, the shielding member (metal TIM) 850 may be disposed to cover (e.g., to seal) the second opening 865 of the shield can 860. For example, the shielding member (metal TIM) 850 may have not only a heat dissipation function but also an electromagnetic interference (EMI) shielding function.

According to an embodiment, when the electronic device 800 (or the display 410) is viewed in the first direction (e.g., the z-axis direction or a vertical direction), the vapor chamber 870 may be disposed between the conductive plate 890 (e.g., a metal rear, a metal plate) and the shielding member (metal TIM) 850.

According to an embodiment, when the electronic device 800 (or the display 410) is viewed in the first direction (e.g., the z-axis direction or the vertical direction), the second conductive member 801 (e.g., a gasket) may be disposed between the shield can 860 and the vapor chamber 870.

According to an embodiment, the second conductive member 801 (e.g., a gasket) may be disposed on an outer region (e.g., a periphery) of the shielding member (metal TIM) 850. For example, the second conductive member 801 (e.g., a gasket) may have a thickness substantially the same as that of the shielding member (metal TIM) 850.

According to an embodiment, the second conductive member 801 (e.g., a gasket) may be electrically connected (e.g., directly or indirectly connected) to the shield can 860 and the vapor chamber 870.

For example, a first surface (e.g., an upper surface) of the second conductive member 801 (e.g., a gasket) may be electrically connected (e.g., directly or indirectly connected) to the shield can 860 (e.g., the third shield can portion 863). For example, a second surface (e.g., a lower surface) of the second conductive member 801 (e.g., a gasket) may be electrically connected (e.g., directly or indirectly connected) to the vapor chamber 870.

According to an embodiment, the first PCB 820 (e.g., a main PCB, a main circuit board) may be electrically connected (e.g., directly or indirectly connected) to the shield can 860, and the vapor chamber 870 may be electrically connected (e.g., directly or indirectly connected) to the conductive plate 890 (e.g., a metal rear, a metal plate). For example, the shield can 860 and the vapor chamber 870 may be electrically connected (e.g., directly or indirectly connected) by the second conductive member 801 (e.g., a gasket) to form a ground path between the first PCB 820 (e.g., a main PCB, a main circuit board) and the vapor chamber 870. For example, the shield can 860 and the vapor chamber 870 may be electrically connected (e.g., directly or indirectly connected) by the second conductive member 801 (e.g., a gasket) to form a ground path between the first PCB 820 (e.g., a main PCB, a main circuit board) and the conductive plate 890 (e.g., a metal rear). Noise (e.g., electromagnetic waves) (e.g., the noise 710 in FIG. 7) may be generated from the processor 830 and the electronic components 821, and the noise 710 (e.g., electromagnetic waves) may be shielded (e.g., removed) through the ground path using the second conductive member 801 (e.g., a gasket).

According to an embodiment, the second conductive member 801 (e.g., a gasket) may include at least one of a conductive gasket, a conductive cushion pad, a conductive silicone gasket, a surface mounter technology (SMT) gasket, a wire mesh gasket, a ground foam gasket, or a fabric over foam gasket.

In an electronic device 800 according to an embodiment of the disclosure, noise 710 (e.g., an electromagnetic wave) generated from the processor 830 and the second PCB 810 (e.g., a processor PCB, a core circuit board) may be shielded (e.g., removed) by forming a ground path contact in a portion adjacent to the processor 830 and the second PCB 810 (e.g., a processor PCB, a core circuit board).

TABLE 2
Performance variation depending on whether shield
can chamber contact structure is applied

| BAND | 28 | 20 | 5 | 8 | 3 | 1 | 7 | 2 | 4 | 66 |
|---|---|---|---|---|---|---|---|---|---|---|
| AP OFF | 97.7 | 97.7 | 95.8 | 95.65 | 96.1 | 95 | 96.2 | 94 | 96.2 | 95.3 |
| Basic State | | | | | | | | | | |
| Comparative Exam. | 92.3 | 91.9 | 91.8 | 92.1 | 92.7 | 94.3 | 95.3 | 92.7 | 94.4 | 93.8 |
| Structure | −5.4 | −5.8 | −3 | −2.55 | −3.4 | −0.7 | −0.9 | −1.3 | −1.8 | −1.5 |
| AP ON Spec. [−3 dB] | | | | | | | | | | |
| With contact structure | 94.6 | 94 | 94.3 | 94.3 | 95.3 | 94.9 | 96.3 | 94.1 | 96.1 | 95.1 |
| AP ON Spec. [−3 dB] | −1.1 | −1.7 | −1.5 | 1.35 | −0.8 | −0.1 | 0.1 | 0.1 | −0.1 | −0.2 |

By applying the second conductive member 801 (e.g., a gasket) to the electronic device 800 to form a ground path between the first PCB 820 (e.g., a main PCB, a main circuit board) and the conductive plate 890 (e.g., a metal rear), the TIS may be improved for the frequency bands (e.g., LTE bands 28, 20, 5, 8, 3, 17, 2, 4, and 66) as indicated in Table 2.

For example, compared to the structure of a comparative example, during the operation (ON) of the processor (AP) 530, the TIS may be improved in each of the frequency bands (e.g., LTE bands 28, 20, 5, 8, 3, 17, 2, 4, and 66). The structure of the comparative example may cause a signal attenuation of −5.4 dB in LTE band 28 when the processor is in operation. On the other hand, when the structure of the electronic device 800 of the disclosure is applied, a signal attenuation of −1.1 [dB] occurs during the operation (ON) of the processor in LTE band 28, which may improve the TIS.

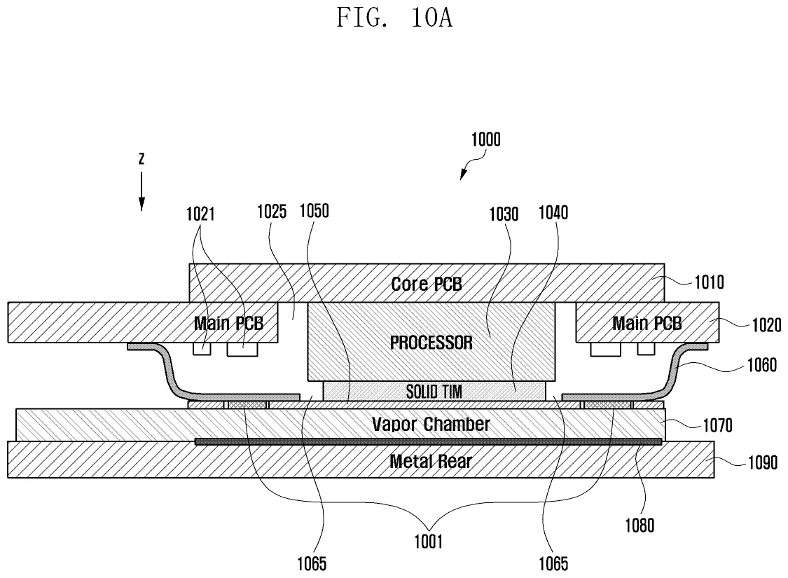

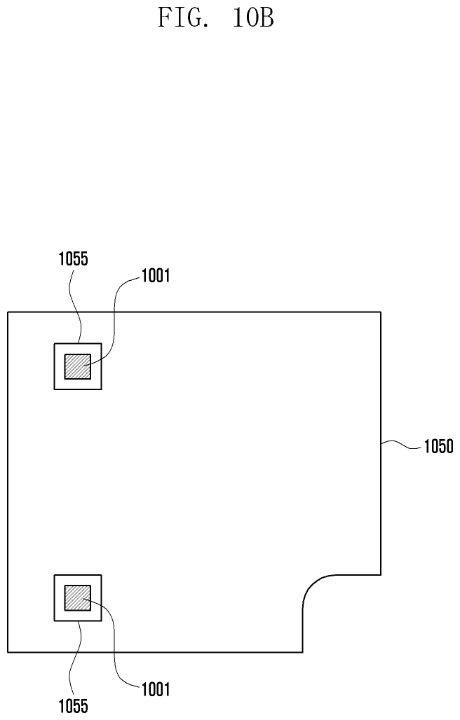

FIG. 10A is a cross-sectional view illustrating an example electronic device, which includes a conductive member (e.g., a conductive gasket) electrically connecting a main PCB and a vapor chamber, according to various embodiments. FIG. 10B is a diagram illustrating an example of how a second conductive member (gasket) is disposed within an opening of a shielding member (e.g., a metal TIM) according to various embodiments.

Referring to FIGS. 10A and 10B, an electronic device 1000 according to an embodiment of the disclosure may include a display module (e.g., the display module 160 of FIG. 4), a first PCB 1020 (e.g., a main PCB, a main circuit board), a second PCB 1010 (e.g., a processor PCB, a core circuit board), a processor 1030 (e.g., an application processor (AP), a central processing unit (CPU)), electronic components 1021, a heat dissipation member 1040 (e.g., a heat dissipation component, a solid thermal interface material (TIM), a heat spreading conducting) paste), a shielding member (metal TIM) 1050 (e.g., a shielding component, a metal TIM, a shielding plate, a metal heat dissipation member, a metal heat dissipation plate), a shield can 1060, a vapor chamber 1070, a first conductive member 1080 (e.g., a conductive double-sided tape, a conductive adhesive layer), a conductive plate 1090 (e.g., a metal rear, a metal plate), and a second conductive member 1001 (e.g., a gasket).

According to an embodiment, a display module (e.g., the display module 160 of FIG. 4) may be disposed on the first PCB 1020 (e.g., a main PCB, a main circuit board). The display module 160 may include a display (e.g., the display 410 of FIG. 4) and a digitizer 460.

According to an embodiment, when the electronic device 1000 (or the display 410) is viewed in a first direction (e.g., the z-axis direction, a vertical direction), the conductive plate 1090 (e.g., a metal rear) may be disposed to face the display 410. Components (e.g., parts) configured to shield noise (e.g., electromagnetic waves) and to dissipate heat (e.g., thermal cooling, heat release) may be disposed between the conductive plate 1090 (e.g., a metal rear, a metal plate) and the display 410.

According to an embodiment, the shielding member (metal TIM) 1050, the shield can 1060, the vapor chamber 1070, the first conductive member 1080 (e.g., a conductive double-sided tape, the conductive adhesive layer), the conductive plate 1090 (e.g., a metal rear, a metal plate), and the second conductive member 1001 (e.g., a gasket) may be disposed to shield noise (e.g., electromagnetic waves) generated from the processor 1030 and the electronic components 1021, and to release heat (e.g., thermal cooling, heat dissipation).

According to an embodiment, the vapor chamber 1070 may be disposed on the conductive plate 1090 (e.g., a metal rear). For example, when the electronic device 1000 (or the display 410) is viewed in a first direction (e.g., the z-axis direction or a vertical direction), the first conductive member 1080 (e.g., a conductive double-sided tape, a conductive adhesive layer) may be disposed between the conductive plate 1090 (e.g., a metal rear, a metal plate) and the vapor chamber 1070. For example, the first conductive member 1080 (e.g., a conductive double-sided tape, a conductive adhesive layer) may electrically connect (e.g., electrically attach) the conductive plate 1090 (e.g., a metal rear, a metal plate) and the vapor chamber 1070.

According to an embodiment, the shielding member (metal TIM) 1050 (e.g., a shield component, a metal TIM, a shield plate, a metal heat dissipation member, a metal heat dissipation plate) may be disposed on the vapor chamber 1070.

For example, the shielding member (metal TIM) 1050 may include a material (e.g., metal) or an alloy (e.g., CuSi) having high electrical and thermal conductivity. For example, the shielding member (metal TIM) 1050 may include a material having high thermal conductivity, such as stainless steel, copper (Cu), nickel (Ni), silver (Ag), gold (Au), silicon (Si), or aluminum (Al). For example, the shielding member (metal TIM) 1050 may include a composite material including a thermally conductive filler or a polymer.

For example, the shielding member (metal TIM) 1050 may be disposed to face (e.g., overlap) the processor 1030 and the electronic components 1021 which generate heat.

According to an embodiment, the heat dissipation member 1040 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member (metal TIM) 1050 to at least partially overlap at least a portion of the shielding member (metal TIM) 1050.

According to an embodiment, the first PCB 1020 (e.g., a main PCB, a main circuit board) may include a first opening 1025. The processor 1030 may be disposed on the second PCB 1010 (e.g., a processor PCB, a core circuit board) by the first opening 1025. For example, the first PCB 1020 (e.g., a main PCB, a main circuit board) may have electronic components 1021 and peripheral circuits disposed thereon. For example, the electronic components 1021 may include a communication module (e.g., the communication module 190 of FIG. 1), and/or a controller.

According to an embodiment, the processor 1030 and core circuits may be disposed on the second PCB 1010 (e.g., a processor PCB, a core circuit board). For example, the core circuits may include a power management integrated circuit (PMIC) (e.g., the power management module 188 of FIG. 1).

According to an embodiment, when the electronic device 1000 (or the display 410) is viewed in the first direction (e.g., the z-axis direction or a vertical direction), the first PCB 1020 (e.g., a main PCB, a main circuit board) may be disposed between the display 410 and the conductive plate 1090 (e.g., a metal rear). For example, when the electronic device 1000 (or the display 410) is viewed in the first direction (e.g., the z-axis direction, a vertical direction), the first PCB 1020 (e.g., a main PCB, a main circuit board) may be disposed between the second PCB 1010 (e.g., a processor PCB, a core circuit board) and the vapor chamber 1070. For example, when the electronic device 1000 (or the display 410) is viewed in the first direction (e.g., the z-axis direction or the vertical direction), the first PCB 1020 (e.g., a main PCB, a main circuit board) may be disposed between the second PCB 1010 (e.g., a processor PCB, a core circuit board) and the shielding member (metal TIM) 1050.

According to an embodiment, when the electronic device 1000 (or the display 410) is viewed in the first direction (e.g., the z-axis direction or a vertical direction), the second PCB 1010 (e.g., a processor PCB, a core circuit board) may be disposed between the display 410 and the conductive plate 1090 (e.g., a metal rear). For example, when the electronic device 1000 (or the display 410) is viewed in the first direction (e.g., the z-axis direction or a vertical direction), the second PCB 1010 (e.g., a processor PCB, a core circuit board) may be disposed between the display 410 and the vapor chamber 1070.

For example, when the electronic device 1000 (or the display 410) is viewed in the first direction (e.g., the z-axis direction or a vertical direction), the second PCB 1010 (e.g., a processor PCB, a core circuit board) may be disposed between the display 410 and the shielding member (metal TIM) 1050.

For example, the processor 1030 may be disposed to be positioned within the first opening 1025. For example, the first PCB 1020 (e.g., a main PCB, a main circuit board) and the second PCB 1010 (e.g., a processor PCB, a core circuit board) may be electrically connected (e.g., directly or indirectly). For example, the first PCB 1020 (e.g., a main PCB, a main circuit board) and the second PCB 1010 (e.g., a processor PCB, a core circuit board) may be electrically connected (e.g., directly or indirectly) through an interposer.

According to an embodiment, the memory (e.g., the memory 130 of FIG. 1, the memory 130 of FIG. 4) may be disposed on the first PCB 1020 and/or the second PCB 1010 (e.g., a processor PCB, a core circuit board).

According to an embodiment, the shield can 1060 may include a second opening 1065. The shield can 1060 may be disposed on the first PCB 1020 (e.g., a main PCB, a main circuit board) so as to surround the peripheral portion of the electronic components 1021.

For example, the shield can 1060 may be disposed to cover at least a portion of the first PCB 1020 (e.g., a main PCB, a main circuit board) and at least a portion of the second PCB 1010 (e.g., a processor PCB, a core circuit board). For example, the shield can 1060 may be disposed to cover the electronic components 1021 disposed on the first PCB 1020 (e.g., a main PCB, a main circuit board) and the processor 1030 disposed on the second PCB 1010 (e.g., a processor PCB, a core circuit board). For example, the shield can 1060 may have not only a heat dissipation function but also an electromagnetic interface (EMI) shielding function.

For example, a first shield can portion of the shield can 1060 may be electrically connected (e.g., directly or indirectly connected) to the first PCB 1020 (e.g., a main PCB or a main circuit board). A second shield can portion of the shield can 1060 may be electrically connected (e.g., directly or indirectly connected) to the shielding member 1050 (e.g., a metal TIM) and the second conductive member 1001 (e.g., a gasket).

According to an embodiment, the heat dissipation member 1040 (e.g., a heat dissipation component, a solid thermal interface material (TIM), a heat-shielding (heat-conducting) member, thermal grease, a heat dissipation paste, a heat-spreading (heat-conducting) paste) may be disposed between the processor 1030 and the shielding member (metal TIM) 1050.

For example, the heat dissipation member 1040 may be disposed to face (e.g., overlap) the processor 1030 so as to release (e.g., cool or diffuse) heat generated by the processor 1030. For example, the shielding member (metal TIM) 1050 may be disposed to face (e.g., overlap) the electronic components 1021 and the processor 1030, so as to release (e.g., cool or diffuse) heat generated from the electronic components 1021 and the processor 1030. For example, the shielding member (metal TIM) 1050 may be disposed to cover (e.g., to seal) the second opening 1065 of the shield can 1060. For example, the shielding member (metal TIM) 1050 may have not only a heat dissipation function but also an electromagnetic interference (EMI) shielding function.

According to an embodiment, when the electronic device 1000 (or the display 410) is viewed in the first direction (e.g., the z-axis direction or a vertical direction), the vapor chamber 1070 may be disposed between the conductive plate 1090 (e.g., a metal rear, a metal plate) and the shielding member (metal TIM) 1050.

According to an embodiment, when the electronic device 1000 (or the display 410) is viewed in the first direction (e.g., the z-axis direction or the vertical direction), the second conductive member 1001 (e.g., a gasket) may be disposed between the shield can 1060 and the vapor chamber 1070.

For example, the second conductive member 1001 (e.g., a gasket) may have a thickness substantially the same as that of the shielding member (metal TIM) 1050.

According to an embodiment, the shielding member (metal TIM) 1050 may include a third opening 1055. For example, a second conductive member 801 (e.g., a gasket) may be disposed to be positioned within the third opening 1055 of the shielding member (metal TIM) 1050. For example, by disposing the second conductive member 801 (e.g., a gasket) within the third opening 1055 of the shielding member (metal TIM) 1050, the second conductive member 1001 (e.g., a gasket) may be electrically connected (e.g., directly or indirectly) to the shield can 1060 and the vapor chamber 1070. For example, a first surface (e.g., an upper surface) of the second conductive member 1001 (e.g., a gasket) may be electrically connected (e.g., directly or indirectly connected) to the shield can 1060 (e.g., the third shield can portion 863). For example, a second surface (e.g., a lower surface) of the second conductive member 1001 (e.g., a gasket) may be electrically connected (e.g., directly or indirectly connected) to the vapor chamber 1070.

According to an embodiment, the first PCB 1020 (e.g., a main PCB, a main circuit board) may be electrically connected (e.g., directly or indirectly connected) to the shield can 1060, and the vapor chamber 1070 may be electrically connected (e.g., directly or indirectly connected) to the conductive plate 1090 (e.g., a metal rear, a metal plate). For example, the shield can 1060 and the vapor chamber 1070 may be electrically connected (e.g., directly or indirectly connected) by the second conductive member 1001 (e.g., a gasket) to form a ground path between the first PCB 1020 (e.g., a main PCB, a main circuit board) and the vapor chamber 1070. For example, the shield can 1060 and the vapor chamber 1070 may be electrically connected (e.g., directly or indirectly connected) by the second conductive member 1001 (e.g., a gasket) to form a ground path between the first PCB 1020 (e.g., a main PCB, a main circuit board) and the conductive plate 1090 (e.g., a metal rear). Noise (e.g., electromagnetic waves) (e.g., the noise 710 in FIG. 7) may be generated from the processor 1030 and the electronic components 1021, and the noise 710 (e.g., electromagnetic waves) may be shielded (e.g., removed) through the ground path using the second conductive member 1001 (e.g., a gasket).

According to an embodiment, the second conductive member 1001 (e.g., a gasket) may include at least one of a conductive gasket, a conductive cushion pad, a conductive silicone gasket, a surface mounter technology (SMT) gasket, a wire mesh gasket, a ground foam gasket, or a fabric over foam gasket.

In an electronic device 1000 according to an embodiment of the disclosure, noise 710 (e.g., an electromagnetic wave) generated from the processor 1030 and the second PCB 1010 (e.g., a processor PCB, a core circuit board) may be shielded (e.g., removed) by forming a ground path contact in a portion adjacent to the processor 1030 and the second PCB 1010 (e.g., a processor PCB, a core circuit board).

By applying the second conductive member 1001 (e.g., a gasket) to the electronic device 1000 to form a ground path between the first PCB 1020 (e.g., a main PCB, a main circuit board) and the conductive plate 1090 (e.g., a metal rear), the TIS may be improved for the frequency bands (e.g., LTE bands 28, 20, 5, 8, 3, 17, 2, 4, and 66) as indicated in Table 2.

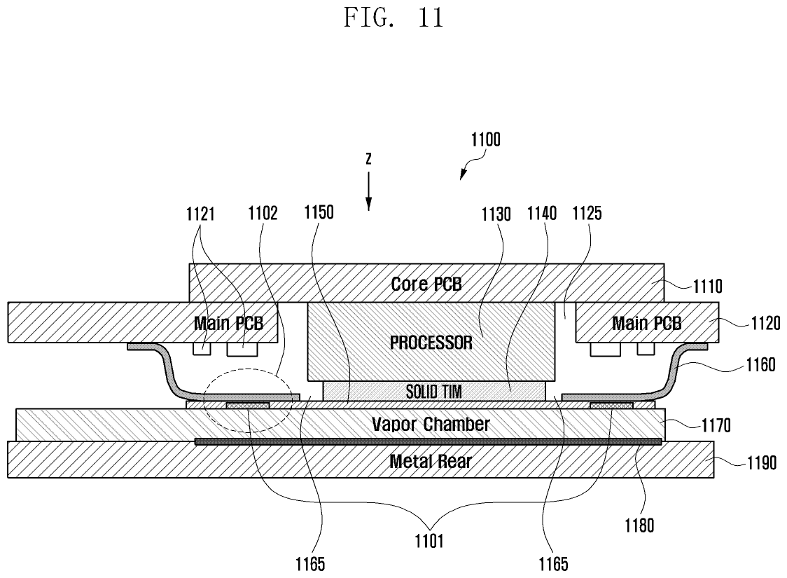

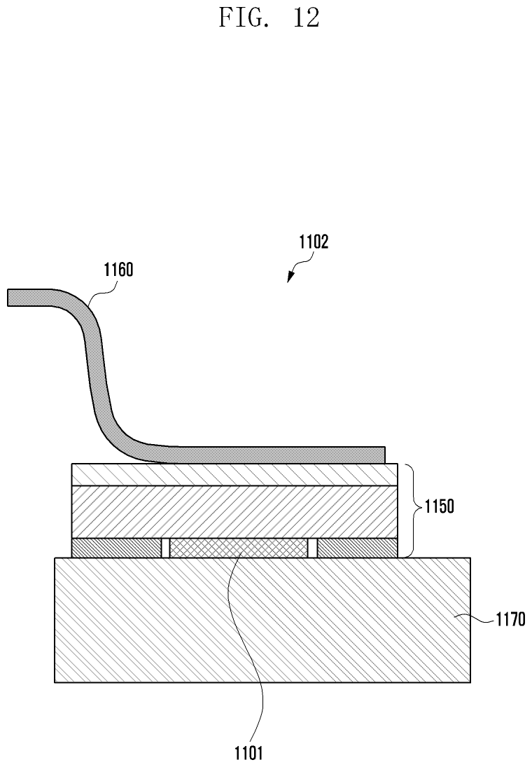

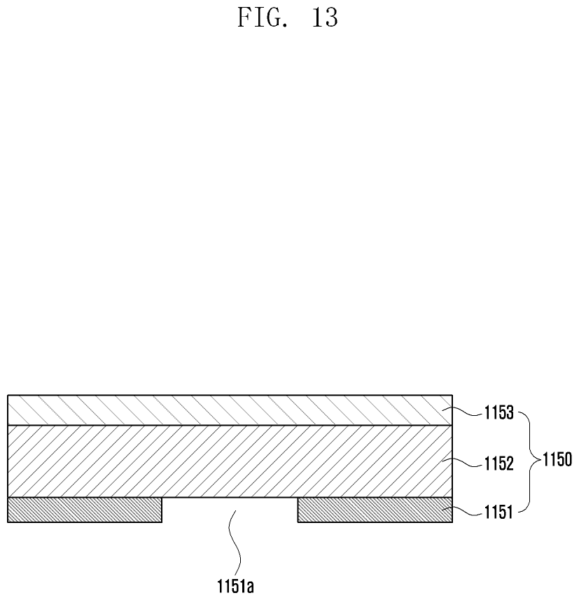

FIG. 11 is a cross-sectional view illustrating an electronic device, including a conductive member (e.g., a conductive gasket) electrically connecting a main PCB and a vapor chamber, according to various embodiments. FIG. 12 is a partial cross-sectional view illustrating an example of how a conductive member (e.g., a conductive gasket) is disposed inside a shielding member (e.g., a metal thermal interface material (metal TIM)) according to various embodiments. FIG. 13 is a cross-sectional view illustrating an example structure of a shielding member (e.g., a metal TIM) according to various embodiments. FIG. 12 illustrates a contact region 1102 in which a second conductive member 1101 (e.g., a gasket) and a vapor chamber 1170 are electrically connected.

Referring to FIGS. 11 to 13, an electronic device 1100 according to an embodiment of the disclosure may include a display module (e.g., the display module 160 of FIG. 4), a first PCB 1120 (e.g., a main PCB, a main circuit board), a second PCB 1110 (e.g., a processor PCB, a core circuit board), a processor 1130 (e.g., an application processor (AP), a central processing unit (CPU)), electronic components 1121, a heat dissipation member 1140 (e.g., a heat dissipation component, a solid thermal interface material (TIM), a heat spreading (heat-conducting) member, thermal grease, a heat dissipation paste, a heat spreading (heat-conducting) paste), a shielding member (metal TIM) 1150 (e.g., a shielding component, a metal TIM, a shielding plate, a metal heat dissipation member, a metal heat dissipation plate), a shield can 1160, a vapor chamber 1170, a first conductive member 1180 (e.g., a conductive double-sided tape, a conductive adhesive layer), a conductive plate 1190 (e.g., a metal rear, a metal plate), and a second conductive member 1101 (e.g., a gasket).

According to an embodiment, a display module (e.g., the display module 160 of FIG. 4) may be disposed on the first PCB 1120 (e.g., a main PCB, a main circuit board). The display module 160 may include a display (e.g., the display 410 of FIG. 4) and a digitizer 460.

According to an embodiment, when the electronic device 1100 (or the display 410) is viewed in a first direction (e.g., the z-axis direction, a vertical direction), the conductive plate 1190 (e.g., a metal rear) may be disposed to face the display 410. Components (e.g., parts) configured to shield noise (e.g., electromagnetic waves) and to dissipate heat (e.g., thermal cooling, heat release) may be disposed between the conductive plate 1190 (e.g., a metal rear, a metal plate) and the display 410.

According to an embodiment, the shielding member (metal TIM) 1150, the shield can 1160, the vapor chamber 1170, the first conductive member 1180 (e.g., a conductive double-sided tape, the conductive adhesive layer), the conductive plate 1190 (e.g., a metal rear, a metal plate), and the second conductive member 1101 (e.g., a gasket) may be disposed to shield noise (e.g., electromagnetic waves) generated from the processor 1130 and the electronic components 1121, and to release heat (e.g., thermal cooling, heat dissipation).

According to an embodiment, the vapor chamber 1170 may be disposed on the conductive plate 1190 (e.g., a metal rear). For example, when the electronic device 1100 (or the display 410) is viewed in a first direction (e.g., the z-axis direction or a vertical direction), the first conductive member 1180 (e.g., a conductive double-sided tape, a conductive adhesive layer) may be disposed between the conductive plate 1190 (e.g., a metal rear, a metal plate) and the vapor chamber 1170. For example, the first conductive member 1180 (e.g., a conductive double-sided tape, a conductive adhesive layer) may electrically connect (e.g., electrically attach) the conductive plate 1190 (e.g., a metal rear, a metal plate) and the vapor chamber 1170.

According to an embodiment, the shielding member (metal TIM) 1150 (e.g., a shield component, a metal TIM, a shield plate, a metal heat dissipation member, a metal heat dissipation plate) may be disposed on the vapor chamber 1170.

For example, the shielding member (metal TIM) 1150 may include a material (e.g., metal) or an alloy (e.g., CuSi) having high electrical and thermal conductivity. For example, the shielding member (metal TIM) 1150 may include a material having high thermal conductivity, such as stainless steel, copper (Cu), nickel (Ni), silver (Ag), gold (Au), silicon (Si), or aluminum (Al). For example, the shielding member (metal TIM) 1150 may include a composite material including a thermally conductive filler or a polymer.

For example, the shielding member (metal TIM) 1150 may be disposed to face (e.g., overlap) the processor 1130 and the electronic components 1121 which generate heat.

According to an embodiment, the heat dissipation member 1140 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member (metal TIM) 1150 to at least partially overlap at least a portion of the shielding member (metal TIM) 1150.

According to an embodiment, the first PCB 1120 (e.g., a main PCB, a main circuit board) may include a first opening 1125. The processor 1130 may be disposed on the second PCB 1110 (e.g., a processor PCB, a core circuit board) by the first opening 1125. For example, the first PCB 1120 (e.g., a main PCB, a main circuit board) may have electronic components 1121 and peripheral circuits disposed thereon. For example, the electronic components 1121 may include a communication module (e.g., the communication module 190 of FIG. 1), and/or a controller.

According to an embodiment, the processor 1130 and core circuits may be disposed on the second PCB 1110 (e.g., a processor PCB, a core circuit board). For example, the core circuits may include a power management integrated circuit (PMIC) (e.g., the power management module 188 of FIG. 1).

According to an embodiment, when the electronic device 1100 (or the display 410) is viewed in the first direction (e.g., the z-axis direction or a vertical direction), the first PCB 1120 (e.g., a main PCB, a main circuit board) may be disposed between the display 410 and the conductive plate 1190 (e.g., a metal rear). For example, when the electronic device 1100 (or the display 410) is viewed in the first direction (e.g., the z-axis direction, a vertical direction), the first PCB 1120 (e.g., a main PCB, a main circuit board) may be disposed between the second PCB 1110 (e.g., a processor PCB, a core circuit board) and the vapor chamber 1170. For example, when the electronic device 1100 (or the display 410) is viewed in the first direction (e.g., the z-axis direction or the vertical direction), the first PCB 1120 (e.g., a main PCB, a main circuit board) may be disposed between the second PCB 1110 (e.g., a processor PCB, a core circuit board) and the shielding member (metal TIM) 1150.

According to an embodiment, when the electronic device 1100 (or the display 410) is viewed in the first direction (e.g., the z-axis direction or a vertical direction), the second PCB 1110 (e.g., a processor PCB, a core circuit board) may be disposed between the display 410 and the conductive plate 1190 (e.g., a metal rear). For example, when the electronic device 1100 (or the display 410) is viewed in the first direction (e.g., the z-axis direction or a vertical direction), the second PCB 1110 (e.g., a processor PCB, a core circuit board) may be disposed between the display 410 and the vapor chamber 1170.

For example, when the electronic device 1100 (or the display 410) is viewed in the first direction (e.g., the z-axis direction or a vertical direction), the second PCB 1110 (e.g., a processor PCB, a core circuit board) may be disposed between the display 410 and the shielding member (metal TIM) 1150.

For example, the processor 1130 may be disposed to be positioned within the first opening 1125. For example, the first PCB 1120 (e.g., a main PCB, a main circuit board) and the second PCB 1110 (e.g., a processor PCB, a core circuit board) may be electrically connected (e.g., directly or indirectly). For example, the first PCB 1120 (e.g., a main PCB, a main circuit board) and the second PCB 1110 (e.g., a processor PCB, a core circuit board) may be electrically connected (e.g., directly or indirectly) through an interposer.

According to an embodiment, the memory (e.g., the memory 130 of FIG. 1, the memory 130 of FIG. 4) may be disposed on the first PCB 1120 and/or the second PCB 1110 (e.g., a processor PCB, a core circuit board).

According to an embodiment, the shield can 1160 may include a second opening 1165. The shield can 1160 may be disposed on the first PCB 1120 (e.g., a main PCB, a main circuit board) so as to surround the peripheral portion of the electronic components 1121.

For example, the shield can 1160 may be disposed to cover at least a portion of the first PCB 1120 (e.g., a main PCB, a main circuit board) and at least a portion of the second PCB 1110 (e.g., a processor PCB, a core circuit board). For example, the shield can 1160 may be disposed to cover the electronic components 1121 disposed on the first PCB 1120 (e.g., a main PCB, a main circuit board) and the processor 1130 disposed on the second PCB 1110 (e.g., a processor PCB, a core circuit board). For example, the shield can 1160 may have not only a heat dissipation function but also an electromagnetic interface (EMI) shielding function.

For example, a first shield can portion of the shield can 1160 may be electrically connected (e.g., directly or indirectly connected) to the first PCB 1120 (e.g., a main PCB or a main circuit board). A second shield can portion of the shield can 1160 may be electrically connected to (e.g., directly or indirectly connected to) the shielding member (metal TIM) 1150. For example, the second conductive member 1101 (e.g., a gasket) may be electrically connected (e.g., indirectly connected) to the shield can 1160 via the shielding member (metal TIM) 1150.

According to an embodiment, the heat dissipation member 1140 (e.g., a heat dissipation component, a solid thermal interface material (TIM), a heat-shielding (heat-conducting) member, thermal grease, a heat dissipation paste, a heat-spreading (heat-conducting) paste) may be disposed between the processor 1130 and the shielding member (metal TIM) 1150.

For example, the heat dissipation member 1140 may be disposed to face (e.g., overlap) the processor 1130 so as to release (e.g., cool or diffuse) heat generated by the processor 1130. For example, the shielding member (metal TIM) 1150 may be disposed to face (e.g., overlap) the electronic components 1121 and the processor 1130, so as to release (e.g., cool or diffuse) heat generated from the electronic components 1121 and the processor 1130. For example, the shielding member (metal TIM) 1150 may be disposed to cover (e.g., to seal) the second opening 1165 of the shield can 1160. For example, the shielding member (metal TIM) 1150 may have not only a heat dissipation function but also an electromagnetic interference (EMI) shielding function.

According to an embodiment, when the electronic device 1100 (or the display 410) is viewed in the first direction (e.g., the z-axis direction or a vertical direction), the vapor chamber 1170 may be disposed between the conductive plate 1190 (e.g., a metal rear, a metal plate) and the shielding member (metal TIM) 1150.

According to an embodiment, when the electronic device 1100 (or the display 410) is viewed in the first direction (e.g., the z-axis direction or the vertical direction), the second conductive member 1101 (e.g., a gasket) may be disposed between the shield can 1160 and the vapor chamber 1170.

According to an embodiment, when the electronic device 1100 (or the display 410) is viewed in the first direction (e.g., the z-axis direction or the vertical direction), the second conductive member 1101 (e.g., a gasket) may be disposed between the shielding member (metal TIM) 1150 and the vapor chamber 1170.

For example, the second conductive member 1101 (e.g., a gasket) may have a thickness that is smaller than that of the shielding member (metal TIM) 1150.

According to an embodiment, the shielding member (metal TIM) 1150 may include a shielding insulation layer 1151 (e.g., a non-conductive layer), a conductive layer 1152 (e.g., a metal conductive layer), and a conductive adhesive layer 1153 (e.g., a conductive double-sided tape). A conductive layer 1152 (e.g., a metal conductive layer) may be disposed on the shielding insulation layer 1151 (e.g., a non-conductive layer). A conductive adhesive layer 1153 (e.g., a conductive double-sided tape) may be disposed on the conductive layer 1152 (e.g., a metal conductive layer). The shielding insulation layer 1151 (e.g., a non-conductive layer) may be disposed to face the vapor chamber 1170. The conductive adhesive layer 1153 (e.g., a conductive double-sided tape) may be disposed to face the shield can 1160. The conductive adhesive layer 1153 (e.g., a conductive double-sided tape) may be electrically connected (e.g., directly or indirectly connected) to the shield can 1160.

For example, the shielding member (metal TIM) 1150 may include a groove 1151a. At least a portion of the shielding insulation layer 1151 (e.g., a non-conductive layer) may be removed to form the groove 1151a. The second conductive member 1101 (e.g., a gasket) may be disposed within the groove 1151a of the shielding member (metal TIM) 1150. By being disposed in the groove 1151a of the shielding member (metal TIM) 1150, the second conductive member 1101 (e.g., a gasket) may be electrically connected (e.g., directly or indirectly connected) to the shielding member (metal TIM) 1150 and the vapor chamber 1170. The second conductive member 1101 (e.g., a gasket) may be electrically connected (e.g., indirectly connected) to the shield can 1160 via the shielding member (metal TIM) 1150. The second conductive member 1101 (e.g., a gasket) may be electrically connected (e.g., directly connected) to the vapor chamber 1170.

According to an embodiment, the first PCB 1120 (e.g., a main PCB, a main circuit board) may be electrically connected (e.g., directly or indirectly connected) to the shield can 1160, and the vapor chamber 1170 may be electrically connected (e.g., directly or indirectly connected) to the conductive plate 1190 (e.g., a metal rear, a metal plate). For example, the shield can 1160 and the vapor chamber 1170 may be electrically connected (e.g., directly or indirectly connected) by the second conductive member 1101 (e.g., a gasket) to form a ground path between the first PCB 1120 (e.g., a main PCB, a main circuit board) and the vapor chamber 1170. For example, the shield can 1160 and the vapor chamber 1170 may be electrically connected (e.g., directly or indirectly connected) by the second conductive member 1101 (e.g., a gasket) to form a ground path between the first PCB 1120 (e.g., a main PCB, a main circuit board) and the conductive plate 1190 (e.g., a metal rear). Noise (e.g., electromagnetic waves) (e.g., the noise 710 in FIG. 7) may be generated from the processor 1130 and the electronic components 1121, and the noise 710 (e.g., electromagnetic waves) may be shielded (e.g., removed) through the ground path using the second conductive member 1101 (e.g., a gasket).

According to an embodiment, the second conductive member 1101 (e.g., a gasket) may include at least one of a conductive gasket, a conductive cushion pad, a conductive silicone gasket, a surface mounter technology (SMT) gasket, a wire mesh gasket, a ground foam gasket, or a fabric over foam gasket.

In an electronic device 1100 according to an embodiment of the disclosure, noise 710 (e.g., an electromagnetic wave) generated from the processor 1130 and the second PCB 1110 (e.g., a processor PCB, a core circuit board) may be shielded (e.g., removed) by forming a ground path contact in a portion adjacent to the processor 1130 and the second PCB 1110 (e.g., a processor PCB, a core circuit board).

By applying the second conductive member 1101 (e.g., a gasket) to the electronic device 1100 to form a ground path between the first PCB 1120 (e.g., a main PCB, a main circuit board) and the conductive plate 1190 (e.g., a metal rear), the TIS may be improved for the frequency bands (e.g., LTE bands 28, 20, 5, 8, 3, 17, 2, 4, and 66) as indicated in Table 2.

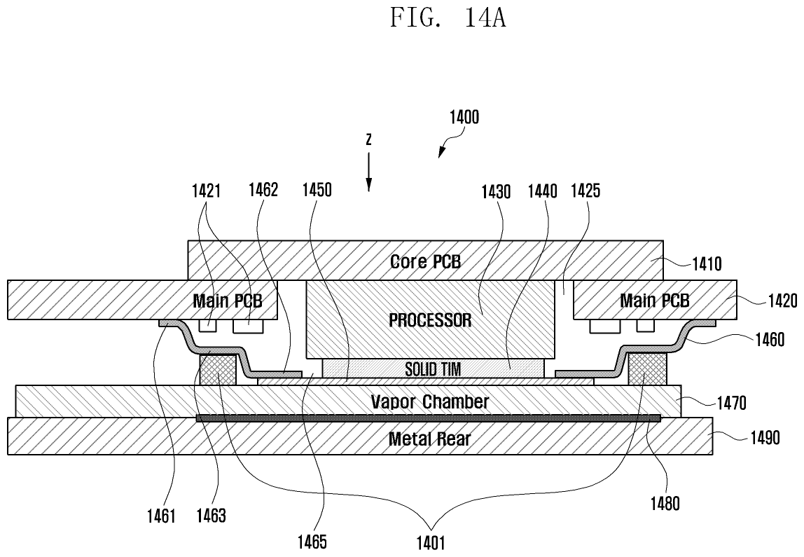

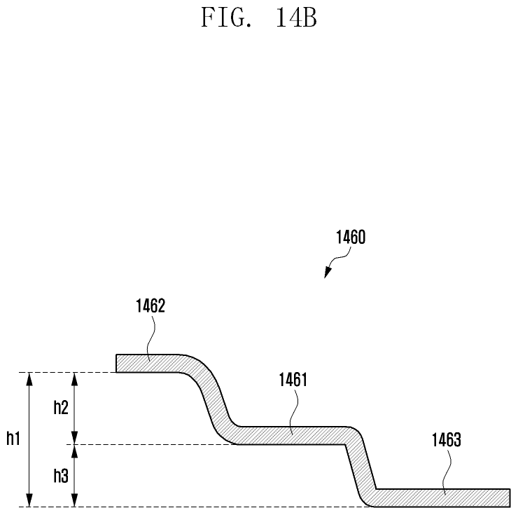

FIG. 14A is a cross-sectional view illustrating an example electronic device, which includes a conductive member (e.g., a conductive gasket) electrically connecting a main PCB and a vapor chamber, according to various embodiments. FIG. 14B is a diagram illustrating the shape of the shield can illustrated in FIG. 14A according to various embodiments.

Referring to FIGS. 14A and 14B, an electronic device 1400 according to an embodiment of the disclosure may include a display module (e.g., the display module 160 of FIG. 4), a first PCB 1420 (e.g., a main PCB, a main circuit board), a second PCB 1410 (e.g., a processor PCB, a core circuit board), a processor 1430 (e.g., an application processor (AP), a central processing unit (CPU)), electronic components 1421, a heat dissipation member 1440 (e.g., a heat dissipation component, a solid thermal interface material (TIM), a heat spreading conducting) paste), a shielding member (metal TIM) 1450 (e.g., a shielding component, a metal TIM, a shielding plate, a metal heat dissipation member, a metal heat dissipation plate), a shield can 1460, a vapor chamber 1470, a first conductive member 1480 (e.g., a conductive double-sided tape, a conductive adhesive layer), a conductive plate 1490 (e.g., a metal rear, a metal plate), and a second conductive member 1401 (e.g., a gasket).

According to an embodiment, a display module (e.g., the display module 160 of FIG. 4) may be disposed on the first PCB 1420 (e.g., a main PCB, a main circuit board). The display module 160 may include a display (e.g., the display 410 of FIG. 4) and a digitizer 460.

According to an embodiment, when the electronic device 1400 (or the display 410) is viewed in a first direction (e.g., the z-axis direction, a vertical direction), the conductive plate 1490 (e.g., a metal rear) may be disposed to face the display 410. Components (e.g., parts) configured to shield noise (e.g., electromagnetic waves) and to dissipate heat (e.g., thermal cooling, heat release) may be disposed between the conductive plate 1490 (e.g., a metal rear, a metal plate) and the display 410.

According to an embodiment, the shielding member (metal TIM) 1450, the shield can 1460, the vapor chamber 1470, the first conductive member 1480 (e.g., a conductive double-sided tape, the conductive adhesive layer), the conductive plate 1490 (e.g., a metal rear, a metal plate), and the second conductive member 1401 (e.g., a gasket) may be disposed to shield noise (e.g., electromagnetic waves) generated from the processor 1430 and the electronic components 1421, and to release heat (e.g., thermal cooling, heat dissipation).

According to an embodiment, the vapor chamber 1470 may be disposed on the conductive plate 1490 (e.g., a metal rear). For example, when the electronic device 1400 (or the display 410) is viewed in a first direction (e.g., the z-axis direction or a vertical direction), the first conductive member 1480 (e.g., a conductive double-sided tape, a conductive adhesive layer) may be disposed between the conductive plate 1490 (e.g., a metal rear, a metal plate) and the vapor chamber 1470. For example, the first conductive member 1480 (e.g., a conductive double-sided tape, a conductive adhesive layer) may electrically connect (e.g., electrically attach) the conductive plate 1490 (e.g., a metal rear, a metal plate) and the vapor chamber 1470.

According to an embodiment, the shielding member (metal TIM) 1450 (e.g., a shield component, a metal TIM, a shield plate, a metal heat dissipation member, a metal heat dissipation plate) may be disposed on the vapor chamber 1470.

For example, the shielding member (metal TIM) 1450 may include a material (e.g., metal) or an alloy (e.g., CuSi) having high electrical and thermal conductivity. For example, the shielding member (metal TIM) 1450 may include a material having high thermal conductivity, such as stainless steel, copper (Cu), nickel (Ni), silver (Ag), gold (Au), silicon (Si), or aluminum (Al). For example, the shielding member (metal TIM) 1450 may include a composite material including a thermally conductive filler or a polymer.

For example, the shielding member (metal TIM) 1450 may be disposed to face (e.g., overlap) the processor 1430 and the electronic components 1421 which generate heat.

According to an embodiment, the heat dissipation member 1440 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member (metal TIM) 1450 to at least partially overlap at least a portion of the shielding member (metal TIM) 1450.

According to an embodiment, the first PCB 1420 (e.g., a main PCB, a main circuit board) may include a first opening 1425. The processor 1430 may be disposed on the second PCB 1410 (e.g., a processor PCB, a core circuit board) by the first opening 1425. For example, the first PCB 1420 (e.g., a main PCB, a main circuit board) may have electronic components 1421 and peripheral circuits disposed thereon. For example, the electronic components 1421 may include a communication module (e.g., the communication module 190 of FIG. 1), and/or a controller.

According to an embodiment, the processor 1430 and core circuits may be disposed on the second PCB 1410 (e.g., a processor PCB, a core circuit board). For example, the core circuits may include a power management integrated circuit (PMIC) (e.g., the power management module 188 of FIG. 1).

According to an embodiment, when the electronic device 1400 (or the display 410) is viewed in the first direction (e.g., the z-axis direction or a vertical direction), the first PCB 1420 (e.g., a main PCB, a main circuit board) may be disposed between the display 410 and the conductive plate 1490 (e.g., a metal rear). For example, when the electronic device 1400 (or the display 410) is viewed in the first direction (e.g., the z-axis direction, a vertical direction), the first PCB 1420 (e.g., a main PCB, a main circuit board) may be disposed between the second PCB 1410 (e.g., a processor PCB, a core circuit board) and the vapor chamber 1470. For example, when the electronic device 1400 (or the display 410) is viewed in the first direction (e.g., the z-axis direction or the vertical direction), the first PCB 1420 (e.g., a main PCB, a main circuit board) may be disposed between the second PCB 1410 (e.g., a processor PCB, a core circuit board) and the shielding member (metal TIM) 1450.

According to an embodiment, when the electronic device 1400 (or the display 410) is viewed in the first direction (e.g., the z-axis direction or a vertical direction), the second PCB 1410 (e.g., a processor PCB, a core circuit board) may be disposed between the display 410 and the conductive plate 1490 (e.g., a metal rear). For example, when the electronic device 1400 (or the display 410) is viewed in the first direction (e.g., the z-axis direction or a vertical direction), the second PCB 1410 (e.g., a processor PCB, a core circuit board) may be disposed between the display 410 and the vapor chamber 1470.

For example, when the electronic device 1400 (or the display 410) is viewed in the first direction (e.g., the z-axis direction or a vertical direction), the second PCB 1410 (e.g., a processor PCB, a core circuit board) may be disposed between the display 410 and the shielding member (metal TIM) 1450.

For example, the processor 1430 may be disposed to be positioned within the first opening 1425. For example, the first PCB 1420 (e.g., a main PCB, a main circuit board) and the second PCB 1410 (e.g., a processor PCB, a core circuit board) may be electrically connected (e.g., directly or indirectly). For example, the first PCB 1420 (e.g., a main PCB, a main circuit board) and the second PCB 1410 (e.g., a processor PCB, a core circuit board) may be electrically connected (e.g., directly or indirectly) through an interposer.

According to an embodiment, the memory (e.g., the memory 130 of FIG. 1, the memory 130 of FIG. 4) may be disposed on the first PCB 1420 and/or the second PCB 1410 (e.g., a processor PCB, a core circuit board).

According to an embodiment, the shield can 1460 may include a second opening 1465. The shield can 1460 may be disposed on the first PCB 1420 (e.g., a main PCB, a main circuit board) so as to surround the peripheral portion of the electronic components 1421.

For example, the shield can 1460 may be disposed to cover at least a portion of the first PCB 1420 (e.g., a main PCB, a main circuit board) and at least a portion of the second PCB 1410 (e.g., a processor PCB, a core circuit board). For example, the shield can 1460 may be disposed to cover the electronic components 1421 disposed on the first PCB 1420 (e.g., a main PCB, a main circuit board) and the processor 1430 disposed on the second PCB 1410 (e.g., a processor PCB, a core circuit board). For example, the shield can 1460 may have not only a heat dissipation function but also an electromagnetic interface (EMI) shielding function.

For example, a first shield can portion 1461 of the shield can 1460 may be electrically connected (e.g., directly or indirectly connected) to the first PCB 1420 (e.g., a main PCB or a main circuit board). A second shield can portion 1462 of the shield can 1460 may be electrically connected to (e.g., directly or indirectly connected to) the shielding member (metal TIM) 1450. A third shield can portion 1463 of the shield can 1460 may be electrically connected (e.g., directly or indirectly connected) to the second conductive member 1401 (e.g., a gasket). For example, the third shield can portion 1463 of the shield can 1460 may be positioned between the first shield can portion 1461 and the second shield can portion 1462. For example, the first shield can portion 1461 and the second shield can portion 1462 of the shield can 1460 may be formed to be inclined (or curved) so as to allow the second shield can portion 1462 of the shield can 1460 and the second conductive member 1401 (e.g., a gasket) to be electrically connected (e.g., directly or indirectly connected). The second shield can portion 1462 and the third shield can portion 1463 of the shield can 1460 may be formed to be inclined (or curved).

According to an embodiment, the heat dissipation member 1440 (e.g., a heat dissipation component, a solid thermal interface material (TIM), a heat-shielding (heat-conducting) member, thermal grease, a heat dissipation paste, a heat-spreading (heat-conducting) paste) may be disposed between the processor 1430 and the shielding member (metal TIM) 1450.

For example, the heat dissipation member 1440 may be disposed to face (e.g., overlap) the processor 1430 so as to release (e.g., cool or diffuse) heat generated by the processor 1430. For example, the shielding member (metal TIM) 1450 may be disposed to face (e.g., overlap) the electronic components 1421 and the processor 1430, so as to release (e.g., cool or diffuse) heat generated from the electronic components 1421 and the processor 1430. For example, the shielding member (metal TIM) 1450 may be disposed to cover (e.g., to seal) the second opening 1465 of the shield can 1460. For example, the shielding member (metal TIM) 1450 may have not only a heat dissipation function but also an electromagnetic interference (EMI) shielding function.

According to an embodiment, when the electronic device 1400 (or the display 410) is viewed in the first direction (e.g., the z-axis direction or a vertical direction), the vapor chamber 1470 may be disposed between the conductive plate 1490 (e.g., a metal rear, a metal plate) and the shielding member (metal TIM) 1450.

According to an embodiment, when the electronic device 1400 (or the display 410) is viewed in the first direction (e.g., the z-axis direction or the vertical direction), the second conductive member 1401 (e.g., a gasket) may be disposed between the shield can 1460 and the vapor chamber 1470.

According to an embodiment, the second conductive member 1401 (e.g., a gasket) may be disposed on an outer region (e.g., a periphery) of the shielding member (metal TIM) 1450. For example, the second conductive member 1401 (e.g., a gasket) may be formed to be thicker than the shielding member (metal TIM) 1450. For example, the second conductive member 1401 (e.g., a gasket) may be formed to be thicker than the heat dissipation member 1440. For example, the second conductive member 1401 (e.g., a gasket) may have a thickness substantially equal to the sum of the thickness of the shielding member (metal TIM) 1450 and the thickness of the heat dissipation member 1440. For example, the second conductive member 1401 (e.g., a gasket) may be formed to be thicker than the sum of the thickness of the shielding member (metal TIM) 1450 and the thickness of the heat dissipation member 1440.

According to an embodiment, the second conductive member 1401 (e.g., a gasket) may be electrically connected (e.g., directly or indirectly connected) to the shield can 1460 and the vapor chamber 1470.

For example, a first surface (e.g., an upper surface) of the second conductive member 1401 (e.g., a gasket) may be electrically connected (e.g., directly or indirectly connected) to the shield can 1460 (e.g., the third shield can portion 1463). For example, a second surface (e.g., a lower surface) of the second conductive member 1401 (e.g., a gasket) may be electrically connected (e.g., directly or indirectly connected) to the vapor chamber 1470.

According to an embodiment, the first PCB 1420 (e.g., a main PCB, a main circuit board) may be electrically connected (e.g., directly or indirectly connected) to the shield can 1460, and the vapor chamber 1470 may be electrically connected (e.g., directly or indirectly connected) to the conductive plate 1490 (e.g., a metal rear, a metal plate). For example, the shield can 1460 and the vapor chamber 1470 may be electrically connected (e.g., directly or indirectly connected) by the second conductive member 1401 (e.g., a gasket) to form a ground path between the first PCB 1420 (e.g., a main PCB, a main circuit board) and the vapor chamber 1470. For example, the shield can 1460 and the vapor chamber 1470 may be electrically connected (e.g., directly or indirectly connected) by the second conductive member 1401 (e.g., a gasket) to form a ground path between the first PCB 1420 (e.g., a main PCB, a main circuit board) and the conductive plate 1490 (e.g., a metal rear). Noise (e.g., electromagnetic waves) (e.g., the noise 710 in FIG. 7) may be generated from the processor 1430 and the electronic components 1421, and the noise 710 (e.g., electromagnetic waves) may be shielded (e.g., removed) through the ground path using the second conductive member 1401 (e.g., a gasket).

According to an embodiment, the second conductive member 1401 (e.g., a gasket) may include at least one of a conductive gasket, a conductive cushion pad, a conductive silicone gasket, a surface mounter technology (SMT) gasket, a wire mesh gasket, a ground foam gasket, or a fabric over foam gasket.

In an electronic device 1400 according to an embodiment of the disclosure, noise 710 (e.g., an electromagnetic wave) generated from the processor 1430 and the second PCB 1410 (e.g., a processor PCB, a core circuit board) may be shielded (e.g., removed) by forming a ground path contact in a portion adjacent to the processor 1430 and the second PCB 1410 (e.g., a processor PCB, a core circuit board). By applying the second conductive member 1401 (e.g., a gasket) to the electronic device 1400 to form a ground path between the first PCB 1420 (e.g., a main PCB, a main circuit board) and the conductive plate 1490 (e.g., a metal rear), the TIS may be improved for the frequency bands (e.g., LTE bands 28, 20, 5, 8, 3, 17, 2, 4, and 66) as indicated in Table 2.

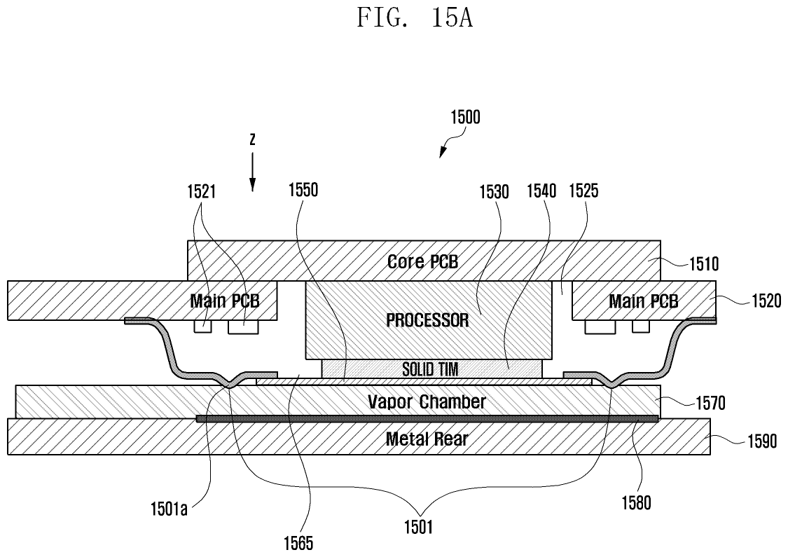

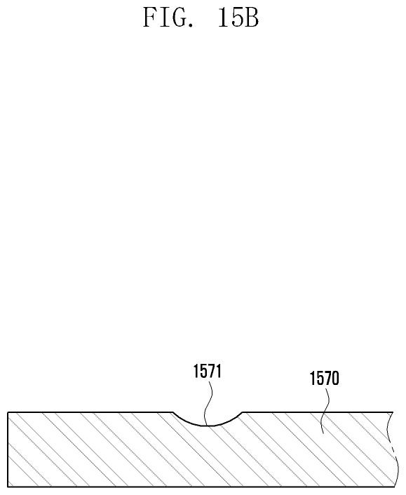

FIG. 15A is a cross-sectional view illustrating an example electronic device including a shield can electrically connecting a main PCB and a vapor chamber according to various embodiments. FIG. 15B is a diagram illustrating a groove formed on an upper surface of the vapor chamber illustrated in FIG. 15A according to various embodiments.

Referring to FIGS. 15A and 15B, an electronic device 1500 according to an embodiment of the disclosure may include a display module (e.g., the display module 160 of FIG. 4), a first PCB 1520 (e.g., a main PCB, a main circuit board), a second PCB 1510 (e.g., a processor PCB, a core circuit board), a processor 1530 (e.g., an application processor (AP), a central processing unit (CPU)), electronic components 1521, a heat dissipation member 1540 (e.g., a heat dissipation component, a solid thermal interface material (TIM), a heat spreading conducting) paste), a shielding member (metal TIM) 1550 (e.g., a shielding component, a metal TIM, a shielding plate, a metal heat dissipation member, a metal heat dissipation plate), a shield can 1501, a vapor chamber 1570, a first conductive member 1580 (e.g., a conductive double-sided tape, a conductive adhesive layer), and a conductive plate 1590 (e.g., a metal rear).

According to an embodiment, a display module (e.g., the display module 160 of FIG. 4) may be disposed on the first PCB 1520 (e.g., a main PCB, a main circuit board). The display module 160 may include a display (e.g., the display 410 of FIG. 4) and a digitizer 460.

According to an embodiment, when the electronic device 1500 (or the display 410) is viewed in a first direction (e.g., the z-axis direction, a vertical direction), the conductive plate 1590 (e.g., a metal rear) may be disposed to face the display 410. Components configured to shield noise (e.g., electromagnetic waves) and to dissipate heat (e.g., thermal cooling, heat release) may be disposed between the conductive plate 1590 (e.g., a metal rear, a metal plate) and the display 410.

According to an embodiment, the shielding member (metal TIM) 1550, the shield can 1501, the vapor chamber 1570, the first conductive member 1580 (e.g., a conductive double-sided tape, the conductive adhesive layer), and the conductive plate 1590 (e.g., a metal rear, a metal plate) may be disposed to shield noise (e.g., electromagnetic waves) generated from the processor 1530 and the electronic components 1521, and to release heat (e.g., thermal cooling, heat dissipation).

According to an embodiment, the vapor chamber 1570 may be disposed on the conductive plate 1590 (e.g., a metal rear). For example, when the electronic device 1500 (or the display 410) is viewed in a first direction (e.g., the z-axis direction or a vertical direction), the first conductive member 1580 (e.g., a conductive double-sided tape, a conductive adhesive layer) may be disposed between the conductive plate 1590 (e.g., a metal rear, a metal plate) and the vapor chamber 1570. For example, the first conductive member 1580 (e.g., a conductive double-sided tape, a conductive adhesive layer) may electrically connect (e.g., electrically attach) the conductive plate 1590 (e.g., a metal rear, a metal plate) and the vapor chamber 1570.

According to an embodiment, the shielding member (metal TIM) 1550 (e.g., a shield component, a metal TIM, a shield plate, a metal heat dissipation member, a metal heat dissipation plate) may be disposed on the vapor chamber 1570.

For example, the shielding member (metal TIM) 1550 may include a material (e.g., metal) or an alloy (e.g., CuSi) having high electrical and thermal conductivity. For example, the shielding member (metal TIM) 1550 may include a material having high thermal conductivity, such as stainless steel, copper (Cu), nickel (Ni), silver (Ag), gold (Au), silicon (Si), or aluminum (Al). For example, the shielding member (metal TIM) 1550 may include a composite material including a thermally conductive filler or a polymer.

For example, the shielding member (metal TIM) 1550 may be disposed to face (e.g., overlap) the processor 1530 and the electronic components 1521 which generate heat.

According to an embodiment, the heat dissipation member 1540 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member (metal TIM) 1550 to at least partially overlap at least a portion of the shielding member (metal TIM) 1550.

According to an embodiment, the first PCB 1520 (e.g., a main PCB, a main circuit board) may include a first opening 1525. The processor 1530 may be disposed on the second PCB 1510 (e.g., a processor PCB, a core circuit board) by the first opening 1525. For example, the first PCB 1520 (e.g., a main PCB, a main circuit board) may have electronic components 1521 and peripheral circuits disposed thereon. For example, the electronic components 1521 may include a communication module (e.g., the communication module 190 of FIG. 1), and/or a controller.

According to an embodiment, the processor 1530 and core circuits may be disposed on the second PCB 1510 (e.g., a processor PCB, a core circuit board). For example, the core circuits may include a power management integrated circuit (PMIC) (e.g., the power management module 188 of FIG. 1).

According to an embodiment, when the electronic device 1500 (or the display 410) is viewed in the first direction (e.g., the z-axis direction or a vertical direction), the first PCB 1520 (e.g., a main PCB, a main circuit board) may be disposed between the display 410 and the conductive plate 1590 (e.g., a metal rear). For example, when the electronic device 1500 (or the display 410) is viewed in the first direction (e.g., the z-axis direction, a vertical direction), the first PCB 1520 (e.g., a main PCB, a main circuit board) may be disposed between the second PCB 1510 (e.g., a processor PCB, a core circuit board) and the vapor chamber 1570. For example, when the electronic device 1500 (or the display 410) is viewed in the first direction (e.g., the z-axis direction or the vertical direction), the first PCB 1520 (e.g., a main PCB, a main circuit board) may be disposed between the second PCB 1510 (e.g., a processor PCB, a core circuit board) and the shielding member (metal TIM) 1550.

According to an embodiment, when the electronic device 1500 (or the display 410) is viewed in the first direction (e.g., the z-axis direction or a vertical direction), the second PCB 1510 (e.g., a processor PCB, a core circuit board) may be disposed between the display 410 and the conductive plate 1590 (e.g., a metal rear). For example, when the electronic device 1500 (or the display 410) is viewed in the first direction (e.g., the z-axis direction or a vertical direction), the second PCB 1510 (e.g., a processor PCB, a core circuit board) may be disposed between the display 410 and the vapor chamber 1570.

For example, when the electronic device 1500 (or the display 410) is viewed in the first direction (e.g., the z-axis direction or a vertical direction), the second PCB 1510 (e.g., a processor PCB, a core circuit board) may be disposed between the display 410 and the shielding member (metal TIM) 1550.

For example, the processor 1530 may be disposed to be positioned within the first opening 1525. For example, the first PCB 1520 (e.g., a main PCB, a main circuit board) and the second PCB 1510 (e.g., a processor PCB, a core circuit board) may be electrically connected (e.g., directly or indirectly). For example, the first PCB 1520 (e.g., a main PCB, a main circuit board) and the second PCB 1510 (e.g., a processor PCB, a core circuit board) may be electrically connected (e.g., directly or indirectly) through an interposer.

According to an embodiment, the memory (e.g., the memory 130 of FIG. 1, the memory 130 of FIG. 4) may be disposed on the first PCB 1520 and/or the second PCB 1510 (e.g., a processor PCB, a core circuit board).

According to an embodiment, the shield can 1501 may include a second opening 1565. The shield can 1501 may be disposed on the first PCB 1520 (e.g., a main PCB, a main circuit board) so as to surround the peripheral portion of the electronic components 1521.

For example, the shield can 1501 may be disposed to cover at least a portion of the first PCB 1520 (e.g., a main PCB, a main circuit board) and at least a portion of the second PCB 1510 (e.g., a processor PCB, a core circuit board). For example, the shield can 1501 may be disposed to cover the electronic components 1521 disposed on the first PCB 1520 (e.g., a main PCB, a main circuit board) and the processor 1530 disposed on the second PCB 1510 (e.g., a processor PCB, a core circuit board). For example, the shield can 1501 may have not only a heat dissipation function but also an electromagnetic interface (EMI) shielding function.

For example, a first shield can portion of the shield can 1501 may be electrically connected (e.g., directly or indirectly connected) to the first PCB 1520 (e.g., a main PCB or a main circuit board). A second shield can portion of the shield can 1501 may be electrically connected to (e.g., directly or indirectly connected to) the vapor chamber 1570.

According to an embodiment, the second shield can portion of the shield can 1501 may include a protrusion 1501a to allow the shield can 1501 to be electrically connected to and fixed to the vapor chamber 1570.

According to an embodiment, a groove 1571 may be formed in at least a portion of the vapor chamber 1570. For example, the groove 1571 of the vapor chamber 1570 may be formed at a position facing the protrusion 1501a formed in the second shield can portion of the shield can 1501. The protrusion 1501a of the second shield can portion may be in contact with the groove 1571 of the vapor chamber 1570, thereby electrically connecting and fixing the shield can 1501 and the vapor chamber 1570.

According to an embodiment, the heat dissipation member 1540 (e.g., a heat dissipation component, a solid thermal interface material (TIM), a heat-shielding (heat-conducting) member, thermal grease, a heat dissipation paste, a heat-spreading (heat-conducting) paste) may be disposed between the processor 1530 and the shielding member (metal TIM) 1550.

For example, the heat dissipation member 1540 may be disposed to face (e.g., overlap) the processor 1530 so as to release (e.g., cool or diffuse) heat generated by the processor 1530. For example, the shielding member (metal TIM) 1550 may be disposed to face (e.g., overlap) the electronic components 1521 and the processor 1530, so as to release (e.g., cool or diffuse) heat generated from the electronic components 1521 and the processor 1530. For example, the shielding member (metal TIM) 1550 may be disposed to cover (e.g., to seal) the second opening 1565 of the shield can 1501. For example, the shielding member (metal TIM) 1550 may have not only a heat dissipation function but also an electromagnetic interference (EMI) shielding function.

According to an embodiment, when the electronic device 1500 (or the display 410) is viewed in the first direction (e.g., the z-axis direction or a vertical direction), the vapor chamber 1570 may be disposed between the conductive plate 1590 (e.g., a metal rear, a metal plate) and the shielding member (metal TIM) 1550.

According to an embodiment, when the electronic device 1500 (or the display 410) is viewed in the first direction (e.g., the z-axis direction, a vertical direction), the shield can 1501 may be disposed between the first PCB 1520 (e.g., a main PCB, a main circuit board) and the vapor chamber 1570.

According to an embodiment, the first PCB 1520 (e.g., a main PCB, a main circuit board) may be electrically connected (e.g., directly or indirectly connected) to the shield can 1501, and the vapor chamber 1570 may be electrically connected (e.g., directly or indirectly connected) to the conductive plate 1590 (e.g., a metal rear, a metal plate). For example, a ground path may be formed between the first PCB 1520 (e.g., a main PCB, a main circuit board) and the vapor chamber 1570 by the shield can 1501. For example, a ground path may be formed between the first PCB 1520 (e.g., a main PCB, a main circuit board) and the conductive plate 1590 (e.g., a metal rear) by the shield can 1501. Noise (e.g., electromagnetic waves) (e.g., the noise 710 of FIG. 7) may be generated from the processor 1530 and the electronic components 1521, and the noise 710 (e.g., electromagnetic waves) may be shielded (e.g., removed) through a ground path using the shield can 1501.

In an electronic device 1500 according to an embodiment of the disclosure, noise 710 (e.g., an electromagnetic wave) generated from the processor 1530 and the second PCB 1510 (e.g., a processor PCB, a core circuit board) may be shielded (e.g., removed) by forming a ground path contact in a portion adjacent to the processor 1530 and the second PCB 1510 (e.g., a processor PCB, a core circuit board). By applying the shield can 1501 to the electronic device 1500 to form a ground path between the first PCB 1520 (e.g., a main PCB, a main circuit board) and the conductive plate 1590 (e.g., a metal rear), the TIS may be improved for the frequency bands (e.g., LTE bands 28, 20, 5, 8, 3, 17, 2, 4, and 66) as indicated in Table 2.

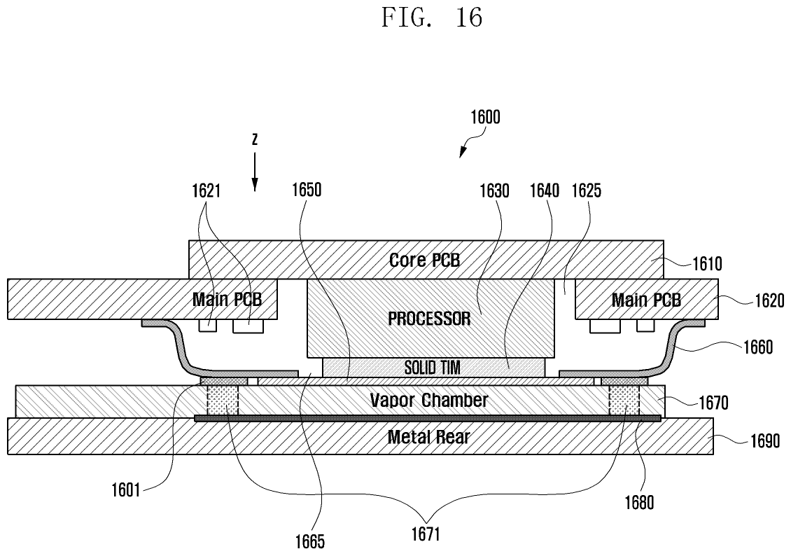

FIG. 16 is a cross-sectional view illustrating an electronic device, including a conductive member (e.g., a conductive gasket) electrically connecting a main PCB and a vapor chamber, according to various embodiments.

Referring to FIG. 16, an electronic device 1600 according to an embodiment of the disclosure may include a display module (e.g., the display module 160 of FIG. 4), a first PCB 1620 (e.g., a main PCB, a main circuit board), a second PCB 1610 (e.g., a processor PCB, a core circuit board), a processor 1630 (e.g., an application processor (AP), a central processing unit (CPU)), electronic components 1621, a heat dissipation member 1640 (e.g., a heat dissipation component, a solid thermal interface material (TIM), a heat spreading (heat-conducting) member, thermal grease, a heat dissipation paste, a heat spreading (heat-conducting) paste), a shielding member (metal TIM) 1650 (e.g., a shielding component, a metal TIM, a shielding plate, a metal heat dissipation member, a metal heat dissipation plate), a shield can 1660, a vapor chamber 1670, a first conductive member 1680 (e.g., a conductive double-sided tape, a conductive adhesive layer), a conductive plate 1690 (e.g., a metal rear, a metal plate), and a second conductive member 1601 (e.g., a gasket).

According to an embodiment, a display module (e.g., the display module 160 of FIG. 4) may be disposed on the first PCB 1620 (e.g., a main PCB, a main circuit board). The display module 160 may include a display (e.g., the display 410 of FIG. 4) and a digitizer 460.

According to an embodiment, when the electronic device 1600 (or the display 410) is viewed in a first direction (e.g., the z-axis direction, a vertical direction), the conductive plate 1690 (e.g., a metal rear) may be disposed to face the display 410. Components (e.g., parts) configured to shield noise (e.g., electromagnetic waves) and to dissipate heat (e.g., thermal cooling, heat release) may be disposed between the conductive plate 1690 (e.g., a metal rear, a metal plate) and the display 410.

According to an embodiment, the shielding member (metal TIM) 1650, the shield can 1660, the vapor chamber 1670, the first conductive member 1680 (e.g., a conductive double-sided tape, the conductive adhesive layer), the conductive plate 1690 (e.g., a metal rear, a metal plate), and the second conductive member 1601 (e.g., a gasket) may be disposed to shield noise (e.g., electromagnetic waves) generated from the processor 1630 and the electronic components 1621, and to release heat (e.g., thermal cooling, heat dissipation).

According to an embodiment, the vapor chamber 1670 may be disposed on the conductive plate 1690 (e.g., a metal rear). For example, when the electronic device 1600 (or the display 410) is viewed in a first direction (e.g., the z-axis direction or a vertical direction), the first conductive member 1680 (e.g., a conductive double-sided tape, a conductive adhesive layer) may be disposed between the conductive plate 1690 (e.g., a metal rear, a metal plate) and the vapor chamber 1670. For example, the first conductive member 1680 (e.g., a conductive double-sided tape, a conductive adhesive layer) may electrically connect (e.g., electrically attach) the conductive plate 1690 (e.g., a metal rear, a metal plate) and the vapor chamber 1670.

According to an embodiment, the shielding member (metal TIM) 1650 (e.g., a shield component, a metal TIM, a shield plate, a metal heat dissipation member, a metal heat dissipation plate) may be disposed on the vapor chamber 1670.

For example, the shielding member (metal TIM) 1650 may include a material (e.g., metal) or an alloy (e.g., CuSi) having high electrical and thermal conductivity. For example, the shielding member (metal TIM) 1650 may include a material having high thermal conductivity, such as stainless steel, copper (Cu), nickel (Ni), silver (Ag), gold (Au), silicon (Si), or aluminum (Al). For example, the shielding member (metal TIM) 1650 may include a composite material including a thermally conductive filler or a polymer.

For example, the shielding member (metal TIM) 1650 may be disposed to face (e.g., overlap) the processor 1630 and the electronic components 1621 which generate heat.

According to an embodiment, the heat dissipation member 1640 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member (metal TIM) 1650 to at least partially overlap at least a portion of the shielding member (metal TIM) 1650.

According to an embodiment, the first PCB 1620 (e.g., a main PCB, a main circuit board) may include a first opening 1625. The processor 1630 may be disposed on the second PCB 1610 (e.g., a processor PCB, a core circuit board) by the first opening 1625. For example, the first PCB 1620 (e.g., a main PCB, a main circuit board) may have electronic components 1621 and peripheral circuits disposed thereon. For example, the electronic components 1621 may include a communication module (e.g., the communication module 190 of FIG. 1), and/or a controller.

According to an embodiment, the processor 1630 and core circuits may be disposed on the second PCB 1610 (e.g., a processor PCB, a core circuit board). For example, the core circuits may include a power management integrated circuit (PMIC) (e.g., the power management module 188 of FIG. 1).

According to an embodiment, when the electronic device 1600 (or the display 410) is viewed in the first direction (e.g., the z-axis direction or a vertical direction), the first PCB 1620 (e.g., a main PCB, a main circuit board) may be disposed between the display 410 and the conductive plate 1690 (e.g., a metal rear). For example, when the electronic device 1600 (or the display 410) is viewed in the first direction (e.g., the z-axis direction, a vertical direction), the first PCB 1620 (e.g., a main PCB, a main circuit board) may be disposed between the second PCB 1610 (e.g., a processor PCB, a core circuit board) and the vapor chamber 1670. For example, when the electronic device 1600 (or the display 410) is viewed in the first direction (e.g., the z-axis direction or the vertical direction), the first PCB 1620 (e.g., a main PCB, a main circuit board) may be disposed between the second PCB 1610 (e.g., a processor PCB, a core circuit board) and the shielding member (metal TIM) 1650.

According to an embodiment, when the electronic device 1600 (or the display 410) is viewed in the first direction (e.g., the z-axis direction or a vertical direction), the second PCB 1610 (e.g., a processor PCB, a core circuit board) may be disposed between the display 410 and the conductive plate 1690 (e.g., a metal rear). For example, when the electronic device 1600 (or the display 410) is viewed in the first direction (e.g., the z-axis direction or a vertical direction), the second PCB 1610 (e.g., a processor PCB, a core circuit board) may be disposed between the display 410 and the vapor chamber 1670.

For example, when the electronic device 1600 (or the display 410) is viewed in the first direction (e.g., the z-axis direction or a vertical direction), the second PCB 1610 (e.g., a processor PCB, a core circuit board) may be disposed between the display 410 and the shielding member (metal TIM) 1650.

For example, the processor 1630 may be disposed to be positioned within the first opening 1625. For example, the first PCB 1620 (e.g., a main PCB, a main circuit board) and the second PCB 1610 (e.g., a processor PCB, a core circuit board) may be electrically connected (e.g., directly or indirectly). For example, the first PCB 1620 (e.g., a main PCB, a main circuit board) and the second PCB 1610 (e.g., a processor PCB, a core circuit board) may be electrically connected (e.g., directly or indirectly) through an interposer.

According to an embodiment, the memory (e.g., the memory 130 of FIG. 1, the memory 130 of FIG. 4) may be disposed on the first PCB 1620 and/or the second PCB 1610 (e.g., a processor PCB, a core circuit board).

According to an embodiment, the shield can 1660 may include a second opening 1665. The shield can 1660 may be disposed on the first PCB 1620 (e.g., a main PCB, a main circuit board) so as to surround the peripheral portion of the electronic components 1621.

For example, the shield can 1660 may be disposed to cover at least a portion of the first PCB 1620 (e.g., a main PCB, a main circuit board) and at least a portion of the second PCB 1610 (e.g., a processor PCB, a core circuit board). For example, the shield can 1660 may be disposed to cover the electronic components 1621 disposed on the first PCB 1620 (e.g., a main PCB, a main circuit board) and the processor 1630 disposed on the second PCB 1610 (e.g., a processor PCB, a core circuit board). For example, the shield can 1660 may have not only a heat dissipation function but also an electromagnetic interface (EMI) shielding function.

For example, a first shield can portion of the shield can 1660 may be electrically connected (e.g., directly or indirectly connected) to the first PCB 1620 (e.g., a main PCB or a main circuit board). A second shield can portion of the shield can 1660 may be electrically connected to (e.g., directly or indirectly connected to) the shielding member (metal TIM) 1650. A third shield can portion of the shield can 1660 may be electrically connected (e.g., directly or indirectly connected) to the second conductive member 1601 (e.g., a gasket). For example, the third shield can portion of the shield can 1660 may be positioned between the first shield can portion and the second shield can portion.

According to an embodiment, the heat dissipation member 1640 (e.g., a heat dissipation component, a solid thermal interface material (TIM), a heat-shielding (heat-conducting) member, thermal grease, a heat dissipation paste, a heat-spreading (heat-conducting) paste) may be disposed between the processor 1630 and the shielding member (metal TIM) 1650.

For example, the heat dissipation member 1640 may be disposed to face (e.g., overlap) the processor 1630 so as to release (e.g., cool or diffuse) heat generated by the processor 1630. For example, the shielding member (metal TIM) 1650 may be disposed to face (e.g., overlap) the electronic components 1621 and the processor 1630, so as to release (e.g., cool or diffuse) heat generated from the electronic components 1621 and the processor 1630. For example, the shielding member (metal TIM) 1650 may be disposed to cover (e.g., to seal) the second opening 1665 of the shield can 1660. For example, the shielding member (metal TIM) 1650 may have not only a heat dissipation function but also an electromagnetic interference (EMI) shielding function.

According to an embodiment, when the electronic device 1600 (or the display 410) is viewed in the first direction (e.g., the z-axis direction or a vertical direction), the vapor chamber 1670 may be disposed between the conductive plate 1690 (e.g., a metal rear, a metal plate) and the shielding member (metal TIM) 1650.

According to an embodiment, when the electronic device 1600 (or the display 410) is viewed in the first direction (e.g., the z-axis direction or the vertical direction), the second conductive member 1601 (e.g., a gasket) may be disposed between the shield can 1660 and the vapor chamber 1670.

According to an embodiment, the second conductive member 1601 (e.g., a gasket) may be disposed on an outer region (e.g., a periphery) of the shielding member (metal TIM) 1650. For example, the second conductive member 1601 (e.g., a gasket) may have a thickness substantially the same as that of the shielding member (metal TIM) 1650.

According to an embodiment, the second conductive member 1601 (e.g., a gasket) may be electrically connected (e.g., directly or indirectly connected) to the shield can 1660 and the vapor chamber 1670.

For example, a first surface (e.g., an upper surface) of the second conductive member 1601 (e.g., a gasket) may be electrically connected (e.g., directly or indirectly connected) to the shield can 1660 (e.g., the third shield can portion). For example, a second surface (e.g., a lower surface) of the second conductive member 1601 (e.g., a gasket) may be electrically connected (e.g., directly or indirectly connected) to the vapor chamber 1670.

For example, the vapor chamber 1670 may include a support structure 1671 (e.g., a spacer) configured to support pressure applied in a first direction (e.g., the z-axis direction, a vertical direction). When viewed in the first direction (e.g., the z-axis direction, a vertical direction), the second conductive member 1601 (e.g., a gasket) may be disposed to overlap the support structure 1671 (e.g., a spacer) of the vapor chamber 1670. The second conductive member 1601 (e.g., a gasket) may be disposed at a position corresponding to the support structure 1671 (e.g., a spacer) of the vapor chamber 1670.

According to an embodiment, the first PCB 1620 (e.g., a main PCB, a main circuit board) may be electrically connected (e.g., directly or indirectly connected) to the shield can 1660, and the vapor chamber 1670 may be electrically connected (e.g., directly or indirectly connected) to the conductive plate 1690 (e.g., a metal rear, a metal plate). For example, the shield can 1660 and the vapor chamber 1670 may be electrically connected (e.g., directly or indirectly connected) by the second conductive member 1601 (e.g., a gasket) to form a ground path between the first PCB 1620 (e.g., a main PCB, a main circuit board) and the vapor chamber 1670. For example, the shield can 1660 and the vapor chamber 1670 may be electrically connected (e.g., directly or indirectly connected) by the second conductive member 1601 (e.g., a gasket) to form a ground path between the first PCB 1620 (e.g., a main PCB, a main circuit board) and the conductive plate 1690 (e.g., a metal rear). Noise (e.g., electromagnetic waves) (e.g., the noise 710 in FIG. 7) may be generated from the processor 1630 and the electronic components 1621, and the noise 710 (e.g., electromagnetic waves) may be shielded (e.g., removed) through the ground path using the second conductive member 1601 (e.g., a gasket).

According to an embodiment, the second conductive member 1601 (e.g., a gasket) may include at least one of a conductive gasket, a conductive cushion pad, a conductive silicone gasket, a surface mounter technology (SMT) gasket, a wire mesh gasket, a ground foam gasket, or a fabric over foam gasket.

In an electronic device 1600 according to an embodiment of the disclosure, noise 710 (e.g., an electromagnetic wave) generated from the processor 1630 and the second PCB 1610 (e.g., a processor PCB, a core circuit board) may be shielded (e.g., removed) by forming a ground path contact in a portion adjacent to the processor 1630 and the second PCB 1610 (e.g., a processor PCB, a core circuit board). By applying the second conductive member 1601 (e.g., a gasket) to the electronic device 1600 to form a ground path between the first PCB 1620 (e.g., a main PCB, a main circuit board) and the conductive plate 1690 (e.g., a metal rear), the TIS may be improved for the frequency bands (e.g., LTE bands 28, 20, 5, 8, 3, 17, 2, 4, and 66) as indicated in Table 2.

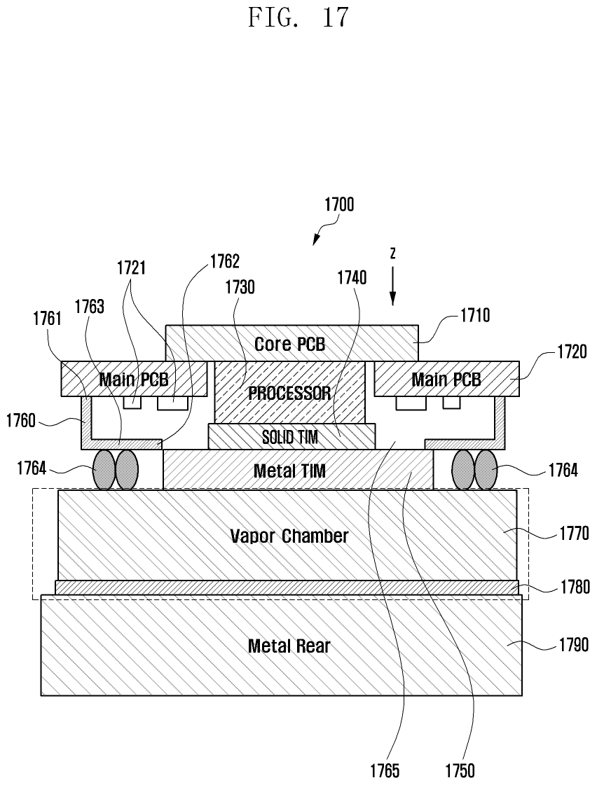

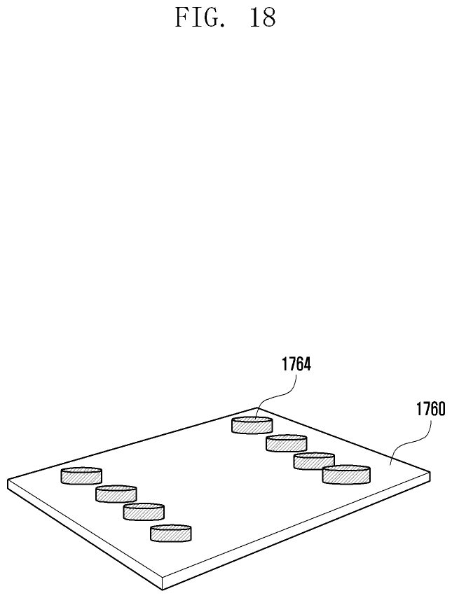

FIG. 17 is a cross-sectional view illustrating an example electronic device including a shield can electrically connecting a main PCB and a vapor chamber according to various embodiments. FIG. 18 is a perspective view illustrating the shield can illustrated in FIG. 17 according to various embodiments.

In describing the electronic device 1700 in FIGS. 17 and 18, detailed descriptions of components that are identical (or similar) to those of the electronic device 800 of FIG. 9, the electronic device 1000 of FIG. 10A, the electronic device 1100 of FIG. 11, the electronic device 1400 of FIG. 14A, the electronic device 1500 of FIG. 15A, and the electronic device 1600 of FIG. 16 may be omitted.

Referring to FIGS. 17 and 18, an electronic device 1700 according to an embodiment of the disclosure may include a display module (e.g., the display module 160 of FIG. 4), a first PCB 1720 (e.g., a main PCB, a main circuit board), a second PCB 1710 (e.g., a processor PCB, a core circuit board), a processor 1730 (e.g., an application processor (AP), a central processing unit (CPU)), electronic components 1721, a heat dissipation member 1740 (e.g., a heat dissipation component, a solid thermal interface material (TIM), a heat spreading (heat-conducting) member, thermal grease, a heat dissipation paste, a heat spreading (heat-conducting) paste), a shielding member (metal TIM) 1750 (e.g., a shielding component, a metal TIM, a shielding plate, a metal heat dissipation member, a metal heat dissipation plate), a shield can 1760, a vapor chamber 1770, a conductive member 1780 (e.g., a conductive double-sided tape, a conductive adhesive layer), and a conductive plate 1790 (e.g., a metal rear).

According to an embodiment, when the electronic device 1700 (or the display) is viewed in a first direction (e.g., the z-axis direction, a vertical direction), the conductive plate 1790 (e.g., a metal rear) may be disposed so as to face the display. Components (e.g., parts) configured to shield noise (e.g., electromagnetic waves) and to dissipate heat (e.g., thermal cooling, heat release) may be disposed between the conductive plate 1790 (e.g., a metal rear, a metal plate) and the display.

According to an embodiment, the shielding member (metal TIM) 1750, the shield can 1760, the vapor chamber 1770, the conductive member 1780 (e.g., a conductive double-sided tape, the conductive adhesive layer), and the conductive plate 1790 (e.g., a metal rear, a metal plate) may be disposed to shield noise (e.g., electromagnetic waves) generated from the processor 1730 and the electronic components 1721, and to release heat (e.g., thermal cooling, heat dissipation).

According to an embodiment, the conductive member 1780 (e.g., a conductive double-sided tape, a conductive adhesive layer) may electrically connect (e.g., electrically attach) the conductive plate 1790 (e.g., a metal rear, a metal plate) and the vapor chamber 1770.

According to an embodiment, the shielding member (metal TIM) 1750 (e.g., a shield component, a metal TIM, a shield plate, a metal heat dissipation member, a metal heat dissipation plate) may be disposed on the vapor chamber 1770.

For example, the shielding member (metal TIM) 1750 may be disposed to face (e.g., overlap) the processor 1730 and the electronic components 1721 which generate heat.

According to an embodiment, the heat dissipation member 1740 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member (metal TIM) 1750 to at least partially overlap at least a portion of the shielding member (metal TIM) 1750.

For example, according to an embodiment, when the electronic device 1700 (or the display) is viewed in the first direction (e.g., the z-axis direction or the vertical direction), the first PCB 1720 (e.g., a main PCB, a main circuit board) may be disposed between the second PCB 1710 (e.g., a processor PCB, a core circuit board) and the shielding member (metal TIM) 1750.

According to an embodiment, when the electronic device 1700 (or the display) is viewed in the first direction (e.g., the z-axis direction, a vertical direction) the first second circuit board 1710 (e.g., a main PCB, a main circuit board) may be disposed between the display and the vapor chamber 1770.

According to an embodiment, when the electronic device 1700 (or the display 410) is viewed in the first direction (e.g., the z-axis direction or a vertical direction), the second PCB 1710 (e.g., a processor PCB, a core circuit board) may be disposed between the display and the shielding member (metal TIM) 1750.

According to an embodiment, when the electronic device 1700 (or the display) is viewed in the first direction (e.g., the z-axis direction, a vertical direction), the shield can 1760 may be disposed between the first PCB 1720 (e.g., a main PCB, a main circuit board) and the vapor chamber 1770.

According to an embodiment, the shield can 1760 may include a second opening 1765. The shield can 1760 may be disposed on the first PCB 1720 (e.g., a main PCB, a main circuit board) so as to surround the peripheral portion of the electronic components 1721.

For example, the shield can 1760 may be disposed to cover at least a portion of the first PCB 1720 (e.g., a main PCB, a main circuit board) and at least a portion of the second PCB 1710 (e.g., a processor PCB, a core circuit board). For example, the shield can 1760 may be disposed to cover the electronic components 1721 disposed on the first PCB 1720 (e.g., a main PCB, a main circuit board) and the processor 1730 disposed on the second PCB 1710 (e.g., a processor PCB, a core circuit board). For example, the shield can 1760 may have not only a heat dissipation function but also an electromagnetic interface (EMI) shielding function.

For example, a first shield can portion 1761 of the shield can 1760 may be electrically connected (e.g., directly or indirectly connected) to the first PCB 1520 (e.g., a main PCB or a main circuit board). The second shield can portion 1762 of the shield can 1501 may be disposed to be in contact with the shield member 1750 (e.g., a metal TIM).

The third shield can portion 1763 of the shield can 1760 may be electrically connected (e.g., directly or indirectly connected) to the vapor chamber 1770. For this purpose, conductive bumps 1764 (e.g., conductive balls) may be formed in the third shield can portion 1763 of the shield can 1760. The conductive bumps 1764 (e.g., conductive balls) formed in the third shield can portion 1763 of the shield can 1760 may be electrically connected to (e.g., directly or indirectly connected to) the first surface (e.g., the upper surface) of the vapor chamber 1770.

According to an embodiment, the heat dissipation member 1740 (e.g., a heat dissipation component, a solid thermal interface material (TIM), a heat-shielding (heat-conducting) member, thermal grease, a heat dissipation paste, a heat-spreading (heat-conducting) paste) may be disposed between the processor 1730 and the shielding member (metal TIM) 1750.

According to an embodiment, when the electronic device 1700 (or the display 410) is viewed in the first direction (e.g., the z-axis direction or a vertical direction), the vapor chamber 1770 may be disposed between the conductive plate 1790 (e.g., a metal rear, a metal plate) and the shielding member (metal TIM) 1750.

According to an embodiment, the first PCB 1720 (e.g., a main PCB, a main circuit board) may be electrically connected (e.g., directly or indirectly connected) to the shield can 1760, and the vapor chamber 1770 may be electrically connected (e.g., directly or indirectly connected) to the conductive plate 1790 (e.g., a metal rear, a metal plate). For example, a ground path may be formed between the first PCB 1720 (e.g., a main PCB, a main circuit board) and the vapor chamber 1770 by the shield can 1760. For example, a ground path may be formed between the first PCB 1720 (e.g., a main PCB, a main circuit board) and the conductive plate 1790 (e.g., a metal rear) by the shield can 1760. Noise (e.g., electromagnetic waves) (e.g., the noise 710 of FIG. 7) may be generated from the processor 1730 and the electronic components 1721, and the noise 710 (e.g., electromagnetic waves) may be shielded (e.g., removed) through a ground path using the shield can 1760.

In an electronic device 1700 according to an embodiment of the disclosure, noise 710 (e.g., electromagnetic waves) generated from the processor 1730 and the second PCB 1710 (e.g., a processor PCB, a core circuit board) may be shielded (e.g., removed) by forming a ground path contact using the shield can 1760. By applying the shield can 1760 to the electronic device 1700 to form a ground path between the first PCB 1720 (e.g., a main PCB, a main circuit board) and the conductive plate 1790 (e.g., a metal rear), the TIS may be improved for the frequency bands (e.g., LTE bands 28, 20, 5, 8, 3, 17, 2, 4, and 66) as indicated in Table 2.

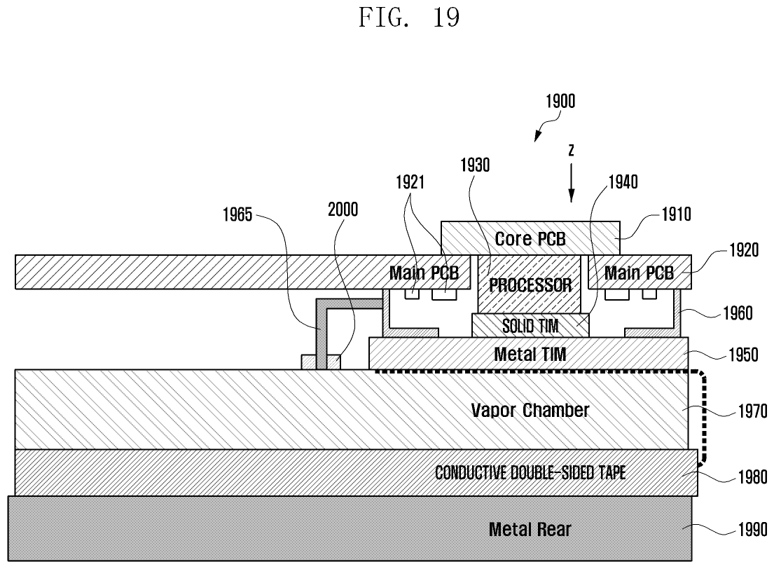

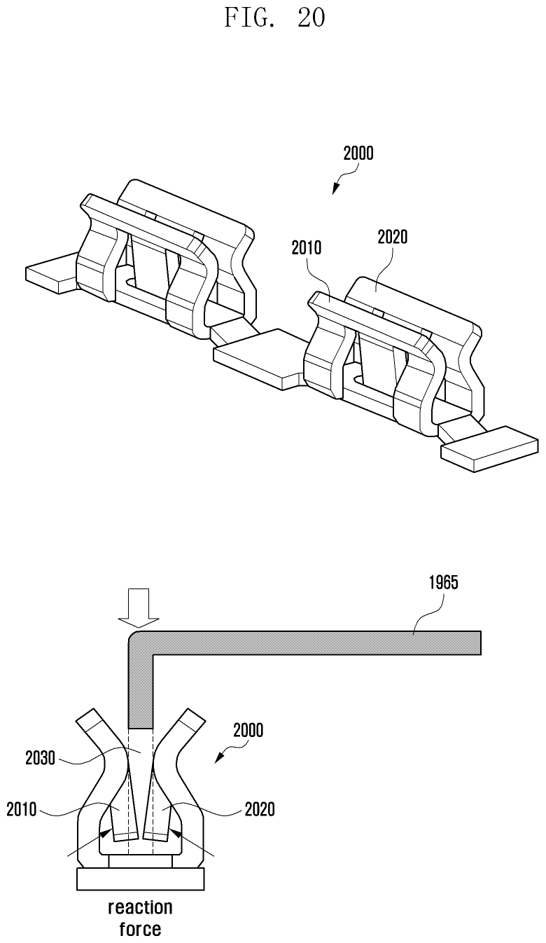

FIG. 19 is a cross-sectional view illustrating an example electronic device including a shield can electrically connecting a main PCB and a vapor chamber according to various embodiments. FIG. 20 is a perspective view and a diagram illustrating how a shield can pin is electrically connected to a conductive clip according to various embodiments.

In describing the electronic device 1900 in FIGS. 19 and 20, detailed descriptions of components that are identical (or similar) to those of the electronic device 800 of FIG. 9, the electronic device 1000 of FIG. 10A, the electronic device 1100 of FIG. 11, the electronic device 1400 of FIG. 14A, the electronic device 1500 of FIG. 15A, the electronic device 1600 of FIG. 16, and the electronic device 1700 of FIG. 17 may be omitted.

Referring to FIGS. 19 and 20, an electronic device 1900 according to an embodiment of the disclosure may include a display module (e.g., the display module 160 of FIG. 4), a first PCB 1920 (e.g., a main PCB, a main circuit board), a second PCB 1910 (e.g., a processor PCB, a core circuit board), a processor 1930 (e.g., an application processor (AP), a central processing unit (CPU)), electronic components 1921, a heat dissipation member 1940 (e.g., a heat dissipation component, a solid thermal interface material (TIM), a heat spreading (heat-conducting) member, thermal grease, a heat dissipation paste, a heat spreading (heat-conducting) paste), a shielding member (metal TIM) 1950 (e.g., a shielding component, a metal TIM, a shielding plate, a metal heat dissipation member, a metal heat dissipation plate), a shield can 1960, a vapor chamber 1970, a conductive member 1980 (e.g., a conductive double-sided tape, a conductive adhesive layer), a conductive plate 1990 (e.g., a metal rear, a metal plate), and a conductive clip 2000.

According to an embodiment, when the electronic device 1900 (or the display) is viewed in a first direction (e.g., the z-axis direction, a vertical direction), the conductive plate 1990 (e.g., a metal rear) may be disposed to face the display. Components (e.g., parts) configured to shield noise (e.g., electromagnetic waves) and to dissipate heat (e.g., thermal cooling, heat release) may be disposed between the conductive plate 1990 (e.g., a metal rear, a metal plate) and the display.

According to an embodiment, the shielding member (metal TIM) 1950, the shield can 1960, the vapor chamber 1970, the conductive member 1980 (e.g., a conductive double-sided tape, the conductive adhesive layer), the conductive plate 1990 (e.g., a metal rear, a metal plate), and the conductive clip 2000 may be disposed to shield noise (e.g., electromagnetic waves) generated from the processor 1930 and the electronic components 1921, and to release heat (e.g., thermal cooling, heat dissipation).

According to an embodiment, the first conductive member 1980 (e.g., a conductive double-sided tape, a conductive adhesive layer) may electrically connect (e.g., electrically attach) the conductive plate 1990 (e.g., a metal rear, a metal plate) and the vapor chamber 1970.

According to an embodiment, the shielding member (metal TIM) 1950 (e.g., a shield component, a metal TIM, a shield plate, a metal heat dissipation member, a metal heat dissipation plate) may be disposed on the vapor chamber 1970.

For example, the shielding member (metal TIM) 1950 may be disposed to face (e.g., overlap) the processor 1930 and the electronic components 1921 which generate heat.

According to an embodiment, the heat dissipation member 1940 (e.g., a heat dissipation component, a solid thermal interface material (TIM), a heat-spreading (heat-conducting) member, thermal grease, a heat dissipation paste, or a heat-spreading (heat-conducting) paste) may be disposed on the shielding member (metal TIM) 1950 to at least partially overlap at least a portion of the shielding member (metal TIM) 1950.

For example, according to an embodiment, when the electronic device 1900 (or the display) is viewed in the first direction (e.g., the z-axis direction or the vertical direction), the first PCB 1920 (e.g., a main PCB, a main circuit board) may be disposed between the second PCB 1910 (e.g., a processor PCB, a core circuit board) and the shielding member (metal TIM) 1950.

According to an embodiment, when the electronic device 1900 (or the display) is viewed in the first direction (e.g., the z-axis direction, a vertical direction), the first second circuit board 1910 (e.g., a main PCB, a main circuit board) may be disposed between the display and the vapor chamber 1970.

According to an embodiment, when the electronic device 1900 (or the display 410) is viewed in the first direction (e.g., the z-axis direction or a vertical direction), the second PCB 1910 (e.g., a processor PCB, a core circuit board) may be disposed between the display and the shielding member (metal TIM) 1950.

According to an embodiment, when the electronic device 1900 (or the display) is viewed in the first direction (e.g., the z-axis direction, a vertical direction), the shield can 1960 may be disposed between the first PCB 1920 (e.g., a main PCB, a main circuit board) and the vapor chamber 1970.

According to an embodiment, the shield can 1960 may include a second opening. The shield can 1960 may be disposed on the first PCB 1920 (e.g., a main PCB, a main circuit board) so as to surround the peripheral portion of the electronic components 1921.

For example, the shield can 1960 may be disposed to cover at least a portion of the first PCB 1920 (e.g., a main PCB, a main circuit board) and at least a portion of the second PCB 1910 (e.g., a processor PCB, a core circuit board). For example, the shield can 1960 may be disposed to cover the electronic components 1921 disposed on the first PCB 1920 (e.g., a main PCB, a main circuit board) and the processor 1930 disposed on the second PCB 1910 (e.g., a processor PCB, a core circuit board). For example, the shield can 1960 may have not only a heat dissipation function but also an electromagnetic interface (EMI) shielding function.

According to an embodiment, a shield can pin 1965 may extend from a portion of the shield can 1960. The shield can 1960 and the shield can pin 1965 may be electrically connected.

According to an embodiment, the conductive clip 2000 may be disposed on a first surface (e.g., an upper surface) of the conductive clip 2000. The conductive clip 2000 and the shield can 1960 may be electrically connected.

For example, at least a portion of the shield can pin 1965 may be coupled (e.g., electrically connected) to the conductive clip 2000. The conductive clip 2000 may include a first clip finger 2010 and a second clip finger 2020 to form a space 2030 therein. The first clip finger 2010 and the second clip finger 2020 may be disposed in a shape facing each other so that a reaction force is applied toward the inner space 2030. When the shield can pin 1965 is coupled (e.g., fitted) into the space 2030 inside the conductive clip 2000, the conductive clip 2000 and the shield can 1960 may be electrically connected.

For example, the first PCB 1920 (e.g., a main PCB, a main circuit board) may be electrically connected (e.g., directly or indirectly connected) to the shield can 1960, and the vapor chamber 1970 may be electrically connected (e.g., directly or indirectly connected) to the conductive plate 1990 (e.g., a metal rear, a metal plate). For example, a ground path may be formed between the first PCB 1920 (e.g., a main PCB, a main circuit board) and the vapor chamber 1970 by the shield can 1960 and the conductive clip 2000. For example, a ground path may be formed between the first PCB 1920 (e.g., a main PCB, a main circuit board) and the conductive plate 1990 (e.g., a metal rear) by the shield can 1960 and the conductive clip 2000. Noise (e.g., electromagnetic waves) (e.g., the noise 710 of FIG. 7) may be generated from the processor 1930 and the electronic components 1921, and the noise 710 (e.g., electromagnetic waves) may be shielded (e.g., removed) through the ground path using the shield can 1960 and the conductive clip 2000.

In an electronic device 1900 according to an embodiment of the disclosure, noise 710 (e.g., electromagnetic waves) generated from the processor 1930 and the second PCB 1910 (e.g., a processor PCB, a core circuit board) may be shielded (e.g., removed) by forming a ground path contact using the shield can 1960 and the conductive clip 2000. By applying the shield can 1960 and the conductive clip 2000 to the electronic device 1900 to form a ground path between the first PCB 1920 (e.g., a main PCB, a main circuit board) and the conductive plate 1990 (e.g., a metal rear), the TIS may be improved for the frequency bands (e.g., LTE bands 28, 20, 5, 8, 3, 17, 2, 4, and 66) as indicated in Table 2.

According to an example embodiment of the disclosure, an electronic device (e.g., the electronic device 101 of FIG. 1, the electronic device 200 of FIG. 2A, the electronic device 300 of FIG. 3A, the electronic device 400 of FIG. 4, the electronic device 500 of FIG. 5, the electronic device 800 of FIG. 9, the electronic device 1000 of FIG. 10A, the electronic device 1100 of FIG. 11, the electronic device 1400 of FIG. 14A, the electronic device 1600 of FIG. 16) may include a display (e.g., the display 410 of FIG. 4), a conductive plate 890 facing the display 410, a first circuit board (e.g., the first PCB 820 of FIG. 9) having a first opening 822 formed therein and an electronic component (e.g., the electronic component 821 of FIG. 9) disposed thereon, a second circuit board (e.g., the second PCB 810 of FIG. 9) having an integrated circuit (e.g., the processor 120 of FIG. 9) disposed thereon to be positioned within the first opening (e.g., the first opening 822 of FIG. 9), a shield can (e.g., the shield can 860 of FIG. 9) having a second opening (e.g., the second opening 865 of FIG. 9) formed therein and disposed on the first circuit board (the first PCB 820) to surround the periphery of the electronic component 821, a shielding member (e.g., the shielding member 850 of FIG. 9) comprising a thermally conductive material configured to cover the second opening 865, a vapor chamber (e.g., the vapor chamber 870 of FIG. 9) disposed between the conductive plate 890 and the shielding member 850 when the display 410 is viewed in a first direction, a first conductive member (e.g., the first conductive member 880 of FIG. 9) comprising a conductive material configured to electrically connect the conductive plate 890 and the vapor chamber 870, and a second conductive member (e.g., the second conductive member 801 of FIG. 9) comprising a conductive material configured to electrically connect the vapor chamber 870 and the shield can 860. When viewed in the first direction, the second conductive member 801 may be disposed so as not to overlap the shielding member 850.

According to an example embodiment, when viewed in the first direction, the first circuit board (the first PCB 820) may be disposed between the display 410 and the conductive plate 890.

According to an example embodiment, when viewed in the first direction, the second circuit board (the second PCB 810) may be disposed between the first circuit board (a first PCB 820) and the conductive plate 890.

According to an example embodiment, when viewed in the first direction, the first conductive member 880 may be disposed between the conductive plate 890 and the vapor chamber 870.

According to an example embodiment, the second conductive member 801 may be disposed on an outer region of the shielding member 850.

According to an example embodiment, the shielding member 850 may include a third opening. The second conductive member 801 may be positioned within the third opening.

According to an example embodiment, when viewed in a second direction perpendicular to the first direction, the second conductive member 801 and the shielding member 850 may be positioned on substantially the same line.

According to an example embodiment, the shielding member 850 may include a conductive layer and a non-conductive layer. A groove may be formed in the non-conductive layer of the shielding member 850. The second conductive member 801 may be positioned within the groove of the non-conductive layer.

According to an example embodiment, the vapor chamber 870 may include a support configured to support pressure applied in the first direction. When viewed in the first direction, the second conductive member 801 may be disposed to overlap the support in the vapor chamber 870.

According to an example embodiment, the shield can 860 may include a first shield can portion 861 electrically connected to the first circuit board (the first PCB 820). The shield can 860 may include a second shield can portion 862 connected to the shielding member 850. The shield can 860 may include a third shield can portion 863 electrically connected to the second conductive member 801.

According to an example embodiment, the second conductive member 801 may include a conductive gasket.

According to an example embodiment, the first conductive member 880 may include a conductive double-sided tape.

According to an example embodiment of the disclosure, an electronic device 101, 200, 300, 400, 500, 800, 1000, 1100, 1400, or 1600 may include a display 410, a conductive plate 890 or 1590 facing the display 410, a first circuit board (a first printed circuit board 820 or 1520) having a first opening 822 or 1522 and an electronic component 821 or 1521 disposed thereon, an integrated circuit (e.g., a processor 120) disposed on the first circuit board such that the integrated circuit (e.g., a processor 120) is positioned within the first opening 822 or 1522, a second circuit board (a second printed circuit board 810 or 1510) having a second opening 865 or 1565 and a shield can 860 or 1501 disposed on the first circuit board (the first printed circuit board 820 or 1520) so as to cover a peripheral portion of the electronic component 821, a shielding member 850 or 1550 comprising a thermally conductive material configured to cover the second opening 865 or 1565, a vapor chamber 870, 1570 disposed between the conductive plate 890 or 1590 and the shielding member 850 or 1550 when the display 410 is viewed in a first direction, and a conductive member (e.g., a conductive double-sided tape) comprising a conductive material configured to electrically connect the conductive plate 890 or 1590 and the vapor chamber 870 or 1570. The shield can 860 or 1501 and the vapor chamber 870 or 1570 may be electrically connected to form a ground path between the first circuit board (the first printed circuit board 820 or 1520) and the conductive plate 890 and 1590.

According to an example embodiment, the shield can 860 or 1501 may be electrically connected to the vapor chamber 870 or 1570 in an outer region of the shielding member 850 or 1550.

According to an example embodiment, the shield can 860 or 1501 may include a first shield can portion 861 electrically connected to the first circuit board (the first printed circuit board 820 or 1520). The shield can 860 or 1501 may include a second shield can portion 862 connected to the shielding member 850 or 1550. The shield can 860 or 1501 may include a third shield can portion 863 electrically connected to the vapor chamber 870 or 1570.

In an electronic device according to an embodiment of the disclosure, noise (e.g., electromagnetic waves) generated from a processor and a second PCB (e.g., a processor PCB, a core circuit board) may be shielded (e.g., removed) by forming a ground path contact in a portion adjacent to the processor and the second PCB (e.g., a processor PCB, a core circuit board). By applying a second conductive member (e.g., a gasket) to the electronic device to form a ground path between a first PCB (e.g., a main PCB or a main circuit board) and a conductive plate (e.g., a metal rear), TIS may be improved for various frequency bands (e.g., LTE bands 28, 20, 5, 8, 3, 17, 2, 4, and 66).

In an electronic device according to an embodiment of the disclosure, noise (e.g., electromagnetic waves) generated from a processor and a second PCB (e.g., a processor PCB, a core circuit board) may be shielded (e.g., removed) by forming a ground path contact using a shield can and a conductive clip. When a shield can and a conductive clip are applied to an electronic device to form a ground path between a first PCB (e.g., a main PCB, a main circuit board) and a conductive plate (e.g., a metal rear), TIS may be improved for frequency bands (e.g., LTE bands 28, 20, 5, 8, 3, 17, 2, 4, and 66).

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a display;
a conductive plate facing the display;
a first circuit board including a first opening and on which an electronic component is disposed;
a second circuit board having an integrated circuit disposed thereon to be positioned within the first opening;
a shield can having a second opening formed therein, the shield can being disposed on the first circuit board to surround a periphery of the electronic component;
a shielding member comprising a thermally conductive material configured to cover the second opening;
a vapor chamber disposed between the conductive plate and the shielding member when the display is viewed in the first direction;
a first conductive member comprising a conductive material configured to electrically connect the conductive plate and the vapor chamber; and
a second conductive member comprising a conductive material configured to electrically connect the vapor chamber and the shield can,
wherein, when viewed in the first direction, the second conductive member is disposed to not overlap the shielding member.

2. The electronic device of claim 1, wherein, when viewed in the first direction, the first circuit board is disposed between the display and the conductive plate.

3. The electronic device of claim 1, wherein, when viewed in the first direction, the second circuit board is disposed between the first circuit board and the conductive plate.

4. The electronic device of claim 1, wherein, when viewed in the first direction, the first conductive member is disposed between the conductive plate and the vapor chamber.

5. The electronic device of claim 1, wherein the second conductive member is disposed on an outer region of the shielding member.

6. The electronic device of claim 1, wherein the shielding member comprises a third opening, and
wherein the second conductive member is positioned within the third opening.

7. The electronic device of claim 5, wherein, when viewed in a second direction perpendicular to the first direction, the second conductive member and the shielding member may be positioned on substantially a same line.

8. The electronic device of claim 1, wherein the shielding member comprises a conductive layer and a non-conductive layer,
wherein a groove is formed in a non-conductive layer of the shielding member, and
wherein the second conductive member is positioned in the groove of the non-conductive layer.

9. The electronic device of claim 1, wherein the vapor chamber comprises a support configured to support pressure applied in the first direction, and
wherein, when viewed in the first direction, the second conductive member is disposed to overlap the support on the vapor chamber.

10. The electronic device of claim 1, wherein the shield can comprises:
a first shield can portion electrically connected to the first circuit board,
a second shield can portion connected to the shielding member, and
a third shield can portion electrically connected to the second conductive member.

11. The electronic device of claim 1, wherein the second conductive member comprises a conductive gasket.

12. The electronic device of claim 1, wherein the first conductive member comprises a conductive double-sided tape.

13. An electronic device comprising:
a display;
a conductive plate facing the display;
a first circuit board including a first opening and on which an electronic component is disposed;
a second circuit board having an integrated circuit disposed thereon to be positioned within the first opening;
a shield can having a second opening formed therein, the shield can being disposed on the first circuit board to surround a periphery of the electronic component;
a shielding member comprising a thermally conductive material configured to cover the second opening;
a vapor chamber disposed between the conductive plate and the shielding member when the display is viewed in a first direction; and
a conductive member comprising a conductive material configured to electrically connect the conductive plate and the vapor chamber,
wherein the shield can and the vapor chamber are electrically connected to form a ground path between the first circuit board and the conductive plate.

14. The electronic device of claim 13, wherein the shield can is electrically connected to the vapor chamber in an outer region of the shielding member.

15. The electronic device of claim 13, wherein the shield can comprises:
a first shield can portion electrically connected to the first circuit board,
a second shield can portion connected to the shielding member, and
a third shield can portion electrically connected to the vapor chamber.
